(19) United States
(12) Patent Application Publication
(10) Pub. No.: US 2025/0293073 A1
(43) Pub. Date: Sep. 18, 2025

(54) RECLAIMABLE DONOR SUBSTRATES FOR USE IN PREPARING MULTIPLE SILICON-ON-INSULATOR STRUCTURES

(71) Applicant: GlobalWafers Co., Ltd., Hsinchu (TW)

(72) Inventors: Carissima M. Hudson, St. Charles, MO (US); JaeWoo Ryu, Plano, TX (US); Michael R. Seacrist, Lake St. Louis, MO (US); Jeffrey L. Libbert, O'Fallon, MO (US)

(21) Appl. No.: 18/607,756

(22) Filed: Mar. 18, 2024

(51) Int. Cl. H01L 21/683; C30B 29/06; C30B 33/02; H01L 21/762

(52) U.S. Cl. CPC H01L 21/6835; C30B 29/06; C30B 33/02; H01L 21/76251; H01L 2221/68363

(57) ABSTRACT

A donor structure for use in preparing silicon-on-insulator structures includes a donor substrate made of single crystal silicon and a dielectric layer formed on a front surface of the donor substrate. The donor substrate has an interstitial oxygen concentration of less than 7.5×10¹⁷ atoms/cm³ and includes a denuded zone extending from the front surface of the donor substrate a denuded zone depth of at least 25 μm. The denuded zone is characterized by non-detectable oxygen precipitates measured by light scattering tomography. The denuded zone depth enables the donor structure to be reclaimed for preparing multiple silicon-on-insulator structures.

### THE FIELD OF THE DISCLOSURE

The present disclosure generally relates to the field of silicon-on-insulator structures. More specifically, the present disclosure relates to silicon substrates used to form device layers in silicon-on-insulator structures characterized by a lack of detectable oxygen precipitates and surface defects, and more particularly, to donor silicon substrates that can be reclaimed to form multiple, defect-free device layers.

### BACKGROUND

Single crystal silicon, which is a starting material for the fabrication of semiconductor electronic devices (e.g., microelectronic devices), is commonly prepared by growing a single crystal silicon ingot by the Czochralski (“CZ”) method. In this method, polycrystalline silicon is charged to a crucible and melted, a seed crystal is brought into contact with the molten silicon, and a single crystal ingot is grown by slow extraction. Other single crystal growth techniques, such as the float zone method, may also be utilized to produce single crystal silicon ingots. The single crystal silicon ingot is trimmed and ground to have one or more flats or notches for proper crystal orientation in subsequent procedures, and is then sliced into individual single crystal silicon wafers.

Silicon wafers may be utilized in the preparation of layered silicon-insulator-semiconductor structures, also referred to as silicon-on-insulator (SOI) structures, that facilitate reducing parasitic capacitance and improving performance of the end device. An SOI structure includes a semiconductor handle wafer, a device layer, and an insulating dielectric film (e.g., an oxide layer) between the handle wafer and the device layer. The device layer is typically a thin layer of single crystal silicon. The semiconductor handle wafer may be made of single crystal silicon, or other suitable semiconductor materials, such as germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

An example process of making an SOI structure includes forming a dielectric layer (e.g., an oxide layer) on a polished front surface of a donor wafer made of single crystal silicon. Particles (e.g., hydrogen atoms or a combination of hydrogen and helium atoms) may be implanted at a specified depth beneath the front surface of the donor wafer. The implanted particles form a cleave plane in the donor wafer at the specified depth at which they were implanted. The surface of the donor wafer may be cleaned to remove organic compounds deposited on the wafer during the implantation process.

The front surface of the donor wafer is then bonded to a handle wafer to form a bonded structure through a hydrophilic bonding process. In some processes, the donor wafer and the handle wafer are bonded together by exposing the surfaces of the wafers to a plasma containing, for example, oxygen or nitrogen. Exposure to the plasma modifies the structure of the surfaces in a process often referred to as surface activation. The wafers are then pressed together and a bond is formed therebetween. The donor wafer is thereafter separated (i.e., cleaved) along the cleave plane from the bonded structure to achieve layer transfer of the device layer from the donor wafer and form the SOI structure.

The continuously shrinking size of the modern microelectronic device imposes challenging restrictions on the quality of the silicon wafers, which is essentially determined by the size and the distribution of the grown-in microdefects. The presence of grown-in defects in an active device region (e.g., in the device layer of a SOI structure) may substantially degrade device performance or even completely kill the device. Grown-in defects include, for example, agglomerates of vacancy-type point defects, agglomerates of interstitial silicon-type point defects (or self-interstitials), and oxygen precipitates (or oxide precipitates). Vacancy-type defects are recognized to be the origin of such observable crystal defects as D-defects (or void defects), flow pattern defects (FPDs), gate oxide integrity defects (GOIs), crystal originated particle defects (COPs), crystal originated light point defects (LPDs), as well as certain classes of bulk defects observed by light scattering techniques such as scanning infrared microscopy and light scattering tomography. Agglomerated self-interstitials generally exist in two forms-globular interstitial clusters, termed B swirl defect (or B-defects), and dislocation loops, termed A swirl defect (or A-defects). Defects relating to self-interstitials may also be referred to as “dislocation clusters.” Oxygen precipitates, such as oxidation-induced stacking faults (OISF) and bulk micro defects (BMD), may grow from nuclei of oxygen or oxygen-containing compounds (e.g., silicon oxide) that form when oxygen dissolves into the silicon ingot during growth.

It is therefore preferred that a portion or all of the silicon crystal ingot, which is subsequently sliced into silicon wafers, be substantially free of grown-in defects. Several approaches for growing substantially defect-free silicon crystals have been reported. These approaches generally involve controlling the ratio of the crystal pull rate (v) to the magnitude of the axial temperature gradient in the vicinity of the interface (G) to within a range above and/or below a critical v/G ratio at which both vacancy-type point defects and self-interstitials are incorporated in very low and comparable concentrations, mutually annihilating each other and thus suppressing the potential formation of any microdefects at lower temperatures. Process conditions, such as growth rate which affects v and hot zone configurations which affect G, can be controlled to determine whether the intrinsic point defects within the single crystal silicon will be predominantly vacancies (where v/G is generally greater than the critical value) or self-interstitials (where v/G is generally less than the critical value). Additionally, the subsequent thermal history of the silicon crystal may be controlled to allow for prolonged diffusion time to suppress the concentration of intrinsic point defects therein, and thus substantially limit or avoid the formation of agglomerated intrinsic point defects in a portion or all of the crystal. See, e.g., U.S. Pat. Nos. 6,287,380; 6,254,672; 5,919,302; 6,312,516 and 6,328,795; the disclosures of each of which are hereby incorporated herein by reference in their entirety. Alternatively, a rapidly cooled silicon (RCS) growth process may be implemented, wherein the subsequent thermal history of the silicon crystal is controlled to rapidly cool at least a portion of the crystal through a target nucleation temperature, in order to control the formation of agglomerated intrinsic point defects in that portion. These approaches may also include allowing at least a portion of the grown crystal to remain above a nucleation temperature for a prolonged period of time, to reduce the concentration of intrinsic point defects prior to rapidly cooling this portion of the crystal through the target nucleation temperature, thus substantially limiting or avoiding the formation of agglomerated intrinsic point defects therein. See, e.g., U.S. Patent Application Publication No. 2003/0196587, the disclosure of which is hereby incorporated herein by reference in its entirety. Still further, methods have been developed to reduce or eliminate agglomerated point defects from the center of the ingot to the edge by the simultaneous control of the cooling rate of the solidified ingot and the radial variation of the axial temperature gradient in the vicinity of the interface (G). See, e.g., U.S. Pat. No. 8,673,248, the disclosure of which is hereby incorporated herein by reference in its entirety.

Silicon wafers sliced from regions of a silicon ingot that lack agglomerated point defects may be referred to as “perfect silicon” or “neutral silicon” wafers. In the context of the present disclosure, “perfect silicon” refers to single crystal silicon wafers sliced from silicon ingots grown under conditions to meet or exceed the standards of Perfect Silicon™ (GlobalWafers Co., Ltd., Hsinchu, TW). These standards include a silicon wafer that meets or exceeds industry specifications for, inter alia, agglomerated defects, DSODs (direct surface oxide defects), COPs, D-Defects, and I-defects (or A-defects). For example, perfect silicon wafers may be characterized by non-detectable FPDs (flow pattern defects measured by the Secco-etching technique) and DSODs (direct surface oxide defect particle count after electric breakdown), and zero I-defects (A-defects) measured by the Secco-etching technique, as well as less than 20 COPs at no more than 0.026 μm size.

In SOI applications, it is preferred that the donor silicon wafer is substantially free of grown-in defects to ensure that the post-transfer device layer does not have surface and bulk defects which can negatively impact device performance. For example, surface imperfections such as void defects and COPs can become holes in the device layer which could result in the breakage of wiring formed on the device layer and kill the device. Oxygen precipitates in the device layer may act as leak current sources and deteriorate the electrical properties of the device. The device layer transferred from the donor silicon wafer is generally thinned and etched to smooth the device layer to a desired roughness (Ra or RMS) specification using a process called epi smoothing. Any surface or bulk defect, such as DSODs, COPs, and oxygen precipitates, can act as a mask to the etch creating defects that will affect device performance. To ensure that the transferred device layer of the SOI structure is defect-free and prevent post-smoothing defectivity, perfect silicon donor wafers may be used with the expectation that the DSOD-free and COP-free perfect silicon donor wafer has a “denuded zone” that is free of oxygen precipitate nuclei and of a sufficient depth in the donor wafer to produce the transferred device layer with no oxygen precipitates that can affect electrical device performance.

Generally, the transferred device layer is very thin (e.g., 100-300 nm in thickness) compared to the thickness of the donor wafer (e.g., greater than 100 μm in thickness), such that a substantial portion of the donor wafer remains after layer transfer. It would be desirable to reclaim the remaining donor wafer after layer transfer for preparing device layers in subsequent SOI structures to minimize costs and material use associated with the preparation of SOI structures. However, SOI processing operations (e.g., oxidation and anneal) performed on the donor wafer create the opportunity for defects, such as COPs and oxygen precipitates, to grow in the donor wafer, even if the donor wafer is originally perfect silicon quality. Growth of defects in the donor wafer during SOI processing imposes limits on the number of times the donor wafer can be reclaimed to produce a defect-free device layer in a subsequent SOI structure. Accordingly, a need exists for a practical, cost-effective solution to eliminate the propensity of surface and bulk defects to grow in silicon donor wafers during SOI processing and facilitate increasing the number of donor wafer reclaims for producing multiple SOI structures.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a donor structure for use in preparing silicon-on-insulator structures is provided. The donor structure includes a donor substrate made of single crystal silicon. The donor substrate includes a front donor substrate surface and has an interstitial oxygen concentration of less than 7.5×10¹⁷ atoms/cm³. The donor structure also includes a dielectric layer formed on the front donor substrate surface. The donor substrate includes a denuded zone extending from the front donor substrate surface a denuded zone depth of at least 25 μm. The denuded zone is characterized by non-detectable oxygen precipitates measured by light scattering tomography.

In another aspect, a multilayer structure is provided. The multilayer structure includes a donor structure including a donor substrate made of single crystal silicon. The donor substrate includes a front donor substrate surface and has an interstitial oxygen concentration of less than 7.5×10¹⁷ atoms/cm³. The donor structure also includes a dielectric layer formed on the front donor substrate surface. The donor substrate includes a denuded zone extending from the front donor substrate surface a denuded zone depth of at least 25 μm. The denuded zone is characterized by non-detectable oxygen precipitates measured by light scattering tomography. The multilayer structure also includes a handle substrate made of single crystal semiconductor material. The handle substrate includes a front handle substrate surface bonded to the dielectric layer such that the dielectric layer is disposed between the handle substrate and the donor substrate.

In another aspect, a method of preparing silicon-on-insulator structures is provided. The method includes bonding a handle substrate made of single crystal semiconductor material to a donor structure to form a bonded structure. The donor structure includes a donor substrate made of single crystal silicon. The donor substrate has an interstitial oxygen concentration of less than 7.5×10¹⁷ atoms/cm³ and includes a front donor substrate surface and a denuded zone extending from the front donor substrate surface a denuded zone depth of at least 25 μm. The denuded zone is characterized by non-detectable oxygen precipitates measured by light scattering tomography. The donor structure also includes a dielectric layer formed on the front donor substrate surface. The bonded structure includes the handle substrate, the donor substrate, and the dielectric layer disposed between the handle substrate and the donor substrate. The method also includes removing a portion of the donor substrate from the bonded structure to form a second donor substrate and a first silicon-on-insulator structure. The first silicon-on-insulator structure includes the handle substrate, the dielectric layer, and a first device layer. The second donor substrate includes a second denuded zone extending from an exposed surface of the second donor substrate a second denuded zone depth that is smaller than the denuded zone depth at least by a thickness of the first device layer. The second denuded zone is characterized by non-detectable oxygen precipitates measured by light scattering tomography. The method also includes forming a second dielectric layer on the exposed surface of the second donor substrate to form a second donor structure, bonding a second handle substrate made of a single crystal semiconductor material to the second donor structure to form a second bonded structure including the second handle substrate, the second donor substrate, and the second dielectric layer disposed between the second handle substrate and the second donor substrate, and removing a portion of the second donor substrate from the second bonded structure to form a third donor substrate and a second silicon-on-insulator structure comprising the second handle substrate, the second dielectric layer, and a second device layer.

In another aspect, a method of preparing a donor structure for use in preparing silicon-on-insulator structures is provided. The method includes performing a heat treatment on a donor substrate made of single crystal silicon. The donor substrate includes a front donor substrate surface and has an interstitial oxygen concentration of less than 7.5×10¹⁷ atoms/cm³. The method also includes forming a dielectric layer on the front donor substrate surface to thereby form the donor structure including the donor substrate and the dielectric layer in interfacial contact with the front donor substrate surface. The heat treatment is performed in an oxidizing gas atmosphere at a temperature and for a duration sufficient such that, when the donor structure is formed, the donor substrate includes a denuded zone extending from the front donor substrate surface a denuded zone depth of at least 25 μm. The denuded zone is characterized by non-detectable oxygen precipitates measured by light scattering tomography.

In another aspect, a method of preparing a multilayer structure is provided. The method includes preparing a donor structure by performing a heat treatment on a donor substrate made of single crystal silicon, the donor substrate including a front donor substrate surface and having an interstitial oxygen concentration of less than 7.5×10¹⁷ atoms/cm³, and forming a dielectric layer on the front donor substrate surface to thereby form the donor structure including the donor substrate and the dielectric layer in interfacial contact with the front donor substrate surface. The heat treatment is performed in an oxidizing gas atmosphere at a temperature and for a duration sufficient such that, when the donor structure is formed, the donor substrate includes a denuded zone extending from the front donor substrate surface a denuded zone depth of at least 25 μm. The denuded zone is characterized by non-detectable oxygen precipitates measured by light scattering tomography. The method also includes bonding a handle substrate made of single crystal semiconductor material to the donor structure to form the multilayer structure including the handle substrate, the donor substrate, and the dielectric layer disposed between the handle substrate and the donor substrate.

In another aspect, a method of preparing silicon-on-insulator structures is provided. The method includes preparing a donor structure by performing a heat treatment on a donor substrate made of single crystal silicon, the donor substrate including a front donor substrate surface and having an interstitial oxygen concentration of less than 7.5×10¹⁷ atoms/cm³, and forming a dielectric layer on the front donor substrate surface to thereby form the donor structure including the donor substrate and the dielectric layer in interfacial contact with the front donor substrate surface. The heat treatment is performed in an oxidizing gas atmosphere at a temperature and for a duration sufficient such that, when the donor structure is formed, the donor substrate includes a denuded zone extending from the front donor substrate surface a denuded zone depth of at least 25 μm. The denuded zone is characterized by non-detectable oxygen precipitates measured by light scattering tomography. The method also includes preparing a multilayer structure by bonding a handle substrate made of single crystal semiconductor material to the donor structure to form the multilayer structure including the handle substrate, the donor substrate, and the dielectric layer disposed between the handle substrate and the donor substrate. The method also includes removing a portion of the donor substrate from the multilayer structure to form a second donor substrate and a first silicon-on-insulator structure including the handle substrate, the dielectric layer, and a first device layer. The second donor substrate includes a second denuded zone extending from an exposed surface of the second donor substrate a second denuded zone depth that is smaller than the denuded zone depth at least by a thickness of the first device layer. The second denuded zone is characterized by non-detectable oxygen precipitates measured by light scattering tomography. The method also includes forming a second dielectric layer on the exposed surface of the second donor substrate to form a second donor structure, bonding a second handle substrate made of a single crystal semiconductor material to the second donor structure to form a second multilayer structure including the second handle substrate, the second donor substrate, and the second dielectric layer disposed between the second handle substrate and the second donor substrate, and removing a portion of the second donor substrate from the second multilayer structure to form a third donor substrate and a second silicon-on-insulator structure including the second handle substrate, the second dielectric layer, and a second device layer.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a depiction of an example silicon-on-insulator structure.

FIG. 2 is a depiction of an example semiconductor handle substrate that may be used in the silicon-on-insulator structure of FIG. 1.

FIG. 3 is a depiction of the handle substrate of FIG. 2 with a semiconductor layer formed on a front surface thereof.

FIG. 4 is a depiction of an example single crystal silicon donor substrate that may be used in the silicon-on-insulator structure of FIG. 1, having a denuded zone formed therein.

FIG. 5 is a depiction of a donor structure including the donor substrate of FIG. 4 and a dielectric layer formed on a front surface thereof.

FIG. 6 is a depiction of the donor structure of FIG. 5, with a cleave plane formed in the donor substrate.

FIG. 7 is a depiction of a bonded structure including the dielectric layer of the donor structure of FIG. 6 bonded to the semiconductor layer deposited on the front surface of the handle substrate of FIG. 3.

FIG. 8 is a depiction of a reclaimed donor substrate that remains after a portion of the donor substrate in the bonded structure of FIG. 7 has been removed to form the silicon-on-insulator structure of FIG. 1.

FIG. 9 depicts an example method of preparing multiple silicon-on-insulator structures from a reclaimable single crystal silicon donor wafer.

FIG. 10 depicts levels of light scattering maps at 0.12 μm particle size or greater generated after successive gas phase selective etching processes performed on test wafers that underwent an ultra-high temperature rapid thermal process (UHT RTP) and test wafers that did not undergo UHT RTP.

FIG. 11A depicts light scattering tomography measurements of test wafers taken using an LST2500 tool to evaluate the bulk micro defect density and precipitate free zone depth following simulated oxidation cycles.

FIG. 11B is a magnified illustration of a bulk micro defect density measurement depicted in FIG. 11A.

FIG. 12A depicts light scattering tomography measurements of test wafers taken using a MO441 tool to evaluate the bulk micro defect density after a two-step oxygen precipitate growth cycle.

FIG. 12B is a magnified illustration of a bulk micro defect density measurement depicted in FIG. 12A.

FIG. 12C depicts light scattering tomography measurements of test wafers taken using a MO441 tool to evaluate the precipitate free zone depth after a two-step oxygen precipitate growth cycle.

FIGS. 13-15 depict levels of light scattering maps taken after a two-step thermal cycle and scanning electron microscope defect images comparing different conditions utilized during an ultra-high temperature rapid thermal process.

FIG. 16 depicts radial bulk micro defect distributions comparing the effect of oxygen precipitate dissolution from different conditions of an ultra-high temperature rapid thermal process.

FIG. 17 is a plot of the radial bulk micro defect distributions depicted in FIG. 16.

Corresponding reference numerals used throughout the drawings indicate corresponding parts.

### DETAILED DESCRIPTION

In example embodiments, silicon donor wafers are provided that are reclaimable and useful in the production of defect-free device layers in multiple silicon-on-insulator (SOI) structures (e.g., two SOI structures, three SOI structures, four SOI structures, five SOI structures, or more than five SOI structures, such as ten SOI structures). The provision of reclaimable silicon donor wafers enables significant cost savings and reduces material losses associated with the preparing of SOI structures. In example embodiments, the silicon donor wafers are made of perfect silicon, also referred to as neutral silicon, which is characterized by non-detectable FPDs (flow pattern defects measured by the Secco-etching technique) and DSODs (direct surface oxide defect particle count after electric breakdown), and zero I-defects (A-defects) measured by the Secco-etching technique, as well as less than 20 COPs at no more than 0.026 μm size. The silicon donor wafers also include a “denuded zone” characterized by non-detectable oxygen precipitates. The denuded zone extends from a front surface of the silicon donor wafer a sufficient depth (e.g., at least 25 micrometers (μm), at least 50 μm, at least 100 μm, at least 200 μm, or at least 300 μm) to enable multiple defect-free device layers to be transferred from the donor wafer. The depth of the denuded zone is facilitated by an ultra-high temperature rapid thermal process (UHT RTP) performed on the silicon donor wafer, which also reduces or maintains low levels of COPs in the silicon donor wafer as well as bulk micro defects (BMDs) within a suitable BMD density range (e.g., less than less than 1×10⁹ cm⁻³, less than 1×10⁸ cm⁻³, less than 1×10⁷ cm⁻³, or less than 5×10⁶ cm⁻³).

Reclaimable donor wafers for producing multiple defect-free device layers in multiple SOI structures must maintain the depth of the denuded zone, low COP level, and low BMD density throughout multiple SOI processes to ensure that the reclaimed donor wafer consistently produces defect-free device layers transferred from the donor wafer. As described herein, the UHT RTP is performed at conditions sufficient to ensure that the denuded zone depth, COP level, and BMD density of the donor wafer of the silicon wafer are maintained across multiple SOI production cycles. This may be confirmed by subjecting the silicon donor wafer to simulated SOI processing cycles followed by light scattering tomography (LST) measurements as well as subjecting the silicon wafer to an oxygen precipitate growth cycle followed by LST. Silicon wafers subjected to the UHT RTP and subsequent SOI processing cycles also show lack of observable levels of laser light scatterings (LLS) at 0.12 μm particle size measured after a gas phase selective etching method, confirming that these wafers are suitable for use as donor wafers with multiple reclaims. COPs in the silicon wafers are dissolved at the UHT RTP conditions, which may be confirmed by scanning electron microscope (SEM) imaging.

In addition to facilitating multiple reclaims of a silicon donor wafer for producing multiple defect-free SOI device layers, the UHT RTP also enables the use of silicon donor wafers having relatively higher levels of interstitial oxygen and/or the use of silicon donor wafers having either vacancies or interstitials as the dominant-type of intrinsic point defect. Typically, preferred silicon donor wafers used in SOI applications are made from perfect silicon having interstitial oxygen levels of lower than about 9 nppma (i.e., about 4.5×10¹⁷ atoms/cm³, as determined by ASTM F121-80) or lower than about 6 nppma (i.e., about 3×10¹⁷ atoms/cm³) and interstitials as the dominant intrinsic point defect to facilitate preventing oxygen precipitates from growing to appreciable size during SOI processing (e.g., oxidation and/or anneal). At higher levels of interstitial oxygen and/or when the perfect silicon has vacancies as the dominant intrinsic point defect, the expectation is that oxygen precipitates will grow to appreciable size in the silicon donor wafer, impacting SOI device layer defectivity and device performance. The narrow range of interstitial oxygen levels and limited dominant intrinsic point defect types that are acceptable in the silicon donor wafer imposes restrictions on the control window and tightens the specifications for the production of these donor wafers, considerably reducing throughput and increasing costs and yield losses. Lower oxygen levels also degrade the strength of the wafer.

In embodiments of the present disclosure, perfect silicon wafers having either vacancies as the dominant intrinsic point defect (also referred to as silicon having a Pv band structure or “Pv silicon”) or interstitials as the dominant intrinsic point defect (also referred to as silicon having a Pi band structure or “Pi silicon”) may be used as donor wafers in SOI structures with multiple reclaims. Additionally, perfect silicon donor wafers with multiple reclaims may include relatively higher levels of interstitial oxygen (e.g., greater than 3×10¹⁷ atoms/cm³, or greater than 4.5×10¹⁷ atoms/cm³, such as up to 6×10¹⁷ atoms/cm³, or up to 7×10¹⁷ atoms/cm³). As described herein, the UHT RTP produces a denuded zone of sufficient depth in the donor wafer to enable oxygen precipitate-free and COP-free device layers throughout multiple SOI processing cycles, even in donor wafers having relatively higher levels of interstitial oxygen and/or having vacancies as the dominant-type of intrinsic point defect. This advantageously widens the control window and acceptable specifications of silicon donor wafers for use in producing SOI structures, which reduces costs and material losses and increases productivity of the front end of silicon crystal manufacture, and allows for wafers having higher oxygen levels and thus higher strength.

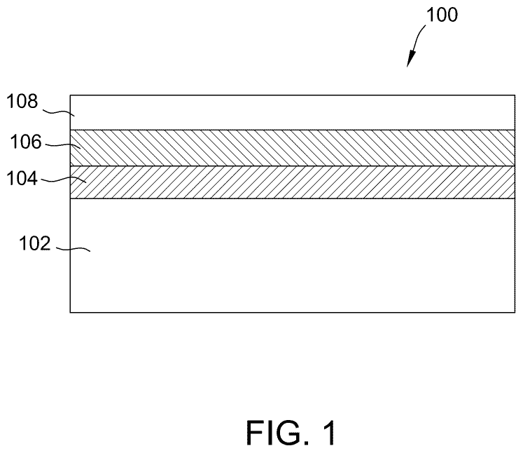

Referring now to the drawings, FIG. 1 depicts an example SOI structure 100 that includes a semiconductor handle substrate or wafer 102, a semiconductor layer 104 (also referred to as a charge trapping layer) disposed on the handle substrate, a dielectric layer 106 (also referred to as a buried oxide or BOX layer) disposed on the semiconductor layer, and a device layer 108 disposed on the dielectric layer. The handle substrate 102 may be made of single crystal silicon, or other suitable semiconductor materials, such as germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

The semiconductor layer 104 is optionally included in the SOI structure 100, and may be included or omitted from the SOI structure depending on the intended application. In some embodiments, the semiconductor layer 104 is included between the handle substrate 102 and the dielectric layer 106 and may improve the performance of end devices fabricated from the SOI structure 100 by acting as a high defectivity layer between the handle substrate 102 and the dielectric layer 106. The semiconductor layer 104 may be made of polycrystalline or amorphous semiconductor material, such as polycrystalline or amorphous silicon (Si), silicon germanium (SiGe), silicon doped with carbon or silicon carbide (SiC), germanium (Ge), and combinations thereof. The semiconductor layer 104 may have any suitable thickness. For example, the thickness of the semiconductor layer 104 may be between about 0.1 μm to about 10 μm, such as between about 0.3 μm to about 5 μm, between about 0.3 μm to about 3 μm, between about 0.3 μm to about 2 μm, or between about 2 μm to about 3 μm. The SOI structure 100 may include defective layers between the handle substrate 102 and the dielectric layer 106 in addition to or in the alternative to the semiconductor layer 104 in some examples. For example, an alternative SOI structure 100 may include heavy ions implanted in the handle substrate 102 to create a near surface damage layer between the handle substrate 102 and the dielectric layer 106. In some examples, the semiconductor layer 104 is not included in the SOI structure 100.

The dielectric layer 106 is disposed over the handle substrate 102 and the semiconductor layer 104 (if included). The dielectric layer 106 acts as an electrical insulator layer between the device layer 108 and the handle substrate 102 to minimize or eliminate leakage currents, lower parasitic capacitance, and otherwise improve the performance of the end device. The material used for the dielectric layer 106 may vary depending on the intended application of the SOI structure 100. In some examples, the dielectric layer 106 may include an oxide or a nitride film. For example, the dielectric layer 106 may include a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof. The dielectric layer 106 may have any suitable thickness. For example, the thickness of the dielectric layer 106 may be at least (i.e., greater than or equal to) 10 nanometers (nm), such as between about 10 nm to about 10 μm, between about 10 nm to about 5 μm, between about 10 nm to about 1 μm, or between about 10 nm to about 800 nm. The thickness of the dielectric layer 106 may be less than about 500 nm, such as less than about 300 nm, less than about 200 nm, less than about 150, or less than about 100 nm. In some embodiments, the thickness of the dielectric layer 106 may be less than about 10 nm.

End devices, such as radiofrequency (RF) devices, are built on and/or in the device layer 108 of the SOI structure 100. In the example SOI structure 100, the device layer 108 is made of single crystal silicon material, and may also be referred to as a silicon device layer 108. The device layer 108 is suitably free of surface and bulk defects that can negatively impact the performance of the end device. In example embodiments, the device layer 108 is made of perfect silicon material that is characterized by non-detectable FPDs and DSODs, zero I-defects (A-defects), and less than 20 crystal originated particle defects (COPs) at no more than 0.026 μm size. The silicon device layer 108 may be characterized by non-detectable oxygen precipitates and a lack of bulk micro defects (BMDs), that is, BMDs within a BMD density range of less than about 1×10⁹ cm⁻³, less than about 1×10⁸ cm⁻³, less than about 1×10⁷ cm⁻³, or less than about 5×10⁶ cm⁻³, measured by LST, and/or a lack of observable levels of laser light scatterings (LLS) at 0.12 μm particle size measured after a gas phase selective etching method.

The device layer 108 may have any suitable thickness. For example, the thickness of the device layer 108 may be between about 10 nm to about 3 μm, such as between about 10 nm to about 1 μm, between about 100 nm to about 1 μm, between about 100 nm to about 500 nm, between about 500 nm to about 1 μm, between about 100 nm to about 300 nm, between about 200 nm to about 500 nm, between about 300 nm to about 700 nm, or between about 400 nm to about 600 nm.

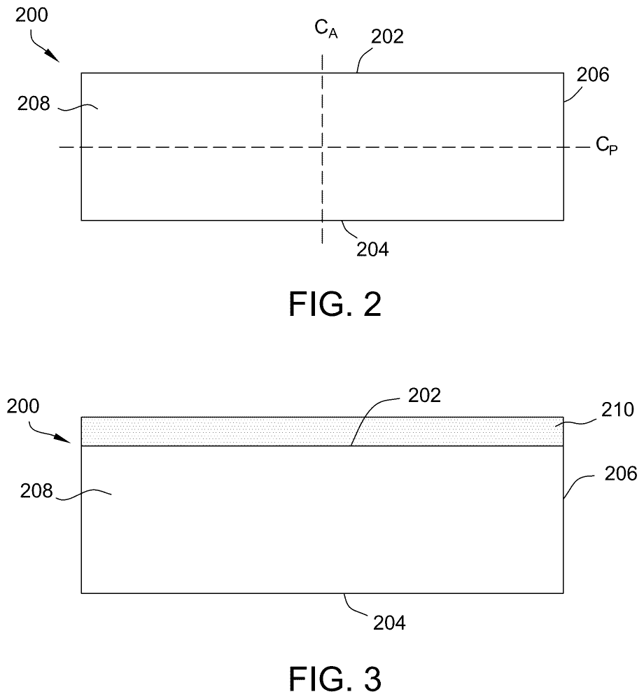

With additional reference to FIGS. 2-7, example methods of preparing the silicon-on-insulator structure 100 will now be described.

FIG. 2 depicts a semiconductor handle substrate 200 that may be used as the handle substrate 102 shown in FIG. 1. The terms “substrate” and “wafer” may be used interchangeably. The handle substrate 200 may be made of any suitable semiconductor material. For example, the handle substrate 200 may be a single crystal semiconductor wafer. In various embodiments, the handle substrate 200 may be made of single crystal silicon, or other suitable semiconductor materials, such as germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

In certain embodiments, the handle substrate 200 is a single crystal semiconductor wafer (e.g., single crystal silicon wafer) sliced from a single crystal ingot grown in accordance with Czochralski (CZ) crystal growing methods or float zone growing methods. Wafers, such as single crystal silicon wafers, for use as the handle substrate 200 may be obtained from commercial suppliers, such as GlobalWafers Co., Ltd., Taiwan. The wafers may be sliced from an ingot using any suitable technique (e.g., a wire saw operation). After slicing, the wafers may be lapped, etched, polished and/or cleaned by suitable techniques. The handle substrate 200, e.g., a single crystal silicon handle substrate, may have a mirror-polished surface finish that is free from surface defects, such as scratches and large particles. For example, the handle substrate 200 may be subjected to a chemical mechanical polishing (“CMP”) operation that typically involves the immersion of a substrate or wafer in an abrasive slurry and polishing of one or both surfaces the substrate by a polymeric pad, whereby through a combination of chemical and mechanical work the surface(s) of the substrate are smoothed to a targeted shape and flatness.

The handle substrate 200 may have interstitial oxygen in any suitable concentration that is generally achieved by the CZ or float zone growing methods. For example, the handle substrate may have an interstitial oxygen concentration of between 1×10¹⁷ atoms/cm³ to about 5×10¹⁸ atoms/cm³. Interstitial oxygen concentration may be measured according to SEMI MF 1188-1105.

The handle substrate 200 may have any resistivity obtainable by the Czochralski or float zone methods. The resistivity of the handle substrate 200 may vary based on the requirements of the end use/application of the SOI structure 100. The resistivity may vary from milliohm or less to megaohm or more. High resistivity handle substrates 200 may have a minimum bulk resistivity of at least about 500 Ohm-cm, such as between about 500 Ohm-cm to about 100,000 Ohm-cm. Low resistivity handle substrates 200 may have a minimum bulk resistivity of below about 100 Ohm-cm, such as between about 1 Ohm-cm to about 100 Ohm-cm. Methods for preparing wafers of varying resistivities are known in the art, and wafers having a desired resistivity may be obtained from commercial suppliers, such as GlobalWafers Co., Ltd., Taiwan.

In some embodiments, the handle substrate 200 may include a p-type or an n-type dopant. Suitable p-type dopants include boron, gallium, or combinations thereof. Suitable n-type dopants include phosphorus, antimony, arsenic, or combinations thereof. The dopant concentration in the handle substrate 200 may be selected based on the desired resistivity of the handle substrate. In some embodiments, the handle substrate 200 is undoped.

The handle substrate 200 includes two major, generally parallel surfaces. One of the surfaces is a front surface 202 (also referred to as a front handle substrate surface, a front handle wafer surface, or a front handle surface), and the other surface is a back surface 204 of the substrate (also referred to as a back handle substrate surface, a back handle wafer surface, or a back handle surface). The handle substrate 200 also includes a circumferential edge 206 joining the front surface 202 and the back surface 204, a bulk region 208 between the front surface 202 and the back surface 204, and a central plane C_{P} between the front surface 202 and the back surface 204. The handle substrate 200 additionally includes an imaginary central axis CA substantially perpendicular to the central plane C_{P}.

A radial length of the handle substrate 200 is measured as the distance between the central axis CA and the circumferential edge 206. A diameter of the handle substrate 200 is measured across the circumferential edge 206. The handle substrate 200 may have any suitable nominal diameter, such as a diameter of at least about 150 mm, at least about 200 mm, at least about 300 mm, or at least about 450 mm. The handle substrate 200 also has a thickness measured as a distance between the front surface 202 and the back surface 204. The handle substrate 200 may have any suitable thickness. For example, the thickness of the handle substrate 200 may be between about 100 μm to about 5000 μm, such as between about 250 μm to about 1500 μm, between about 300 μm and about 1000 μm, or between about 500 μm to about 1000 μm. The handle substrate 200, e.g., a silicon wafer, may have some total thickness variation (TTV), warp, and/or bow, such that the midpoint between every point on the front surface 202 and every point on the back surface 204 may not precisely fall within a plane. As a practical matter, however, the TTV, warp, and bow are typically so slight that to a close approximation the midpoints can be said to fall within the imaginary central plane C_{P} which is approximately equidistant between the front surface 202 and the back surface 204.

Referring to FIG. 3, a semiconductor or charge trapping layer 210 is formed on the front surface 202 of the handle substrate 200. The semiconductor layer 210 forms the semiconductor layer 104 in the SOI structure 100 shown in FIG. 1. Prior to formation of the charge trapping layer 210, the handle substrate 200 may subjected to a pre-treatment operation that includes exposing the surfaces 202 and 204 to an ambient atmosphere comprising reducing agents and/or etching agents to clean the substrate 200 and remove contaminants, such as organic contaminants and boron, aluminum, phosphorus, and the like, from the surfaces 202 and 204. An interfacial layer (e.g., silicon oxide, silicon nitride, or silicon oxynitride) may be formed on the front surface 202 of the handle substrate 200 prior to forming the semiconductor layer 210. The interfacial layer may be formed by suitable techniques, including thermal oxidation or chemical vapor deposition (CVD). Semiconductor material is then deposited onto the exposed front surface 202 of the substrate 200 to form the semiconductor layer 210.

Semiconductor material that may be used to form the semiconductor layer 210 includes any suitable material that is capable of forming a highly defective semiconductor layer 104 in the SOI structure 100. Such semiconductor materials include polycrystalline semiconductor materials and amorphous semiconductor materials. Semiconductor materials that may be polycrystalline or amorphous include, for example, silicon (Si), silicon germanium (SiGe), silicon doped with carbon or silicon carbide (SiC), and germanium (Ge). Silicon germanium includes an alloy of silicon germanium in any molar ratio of silicon and germanium. The term “polycrystalline” denotes a semiconductor material comprising small semiconductor crystals having random crystal orientations. The term “amorphous” denotes a semiconductor material that is in non-crystalline allotropic form, which lacks short range and long range order.

The charge trapping layer 210 may have a resistivity of at least about 1000 Ohm-cm, or at least about 3000 Ohm-cm, such as between about 1000 Ohm-cm and about 100,000 Ohm-cm, or between about 1000 Ohm-cm and about 10,000 Ohm-cm.

The semiconductor layer 210 may be deposited onto the front surface 202 of the handle substrate 200 by any suitable means. For example, the semiconductor material may be deposited using metalorganic chemical vapor deposition (MOCVD), physical vapor deposition (PVD), chemical vapor deposition (CVD), low pressure chemical vapor deposition (LPCVD), plasma enhanced chemical vapor deposition (PECVD), or molecular beam epitaxy (MBE). The deposited semiconductor material may be polycrystalline or amorphous, depending on the desired end form of the semiconductor layer 210.

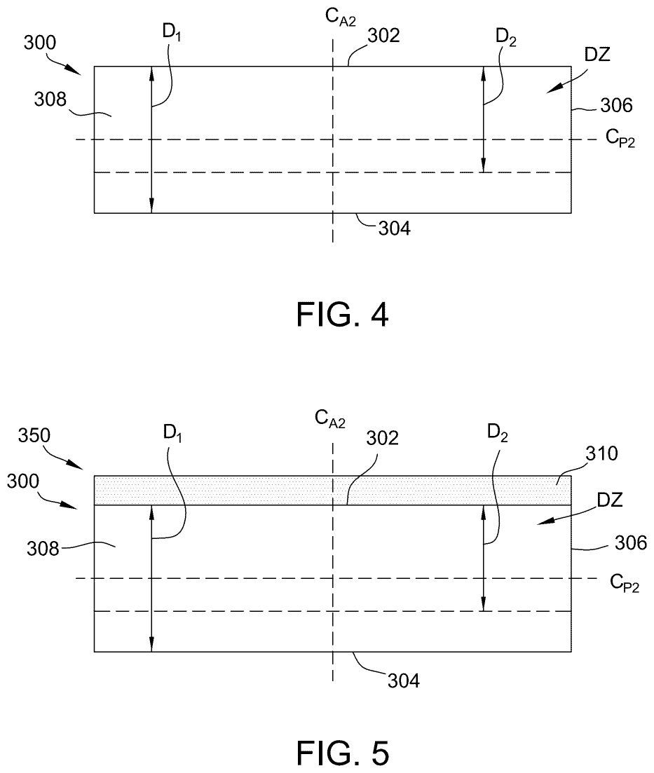

The semiconductor layer 210 may be subsequently planarized to reduce a surface roughness of the exposed surface of the semiconductor layer 210 and optimize warp and bow of the substrate 200 shown in FIG. 4 for subsequent operations in producing the SOI structure 100. For example, the semiconductor layer 210 may be subjected to a polishing operation, such as a CMP operation. In addition to polishing, cleaning of the substrate 200 having the semiconductor layer 210 may optionally be performed. If desired, the handle substrate 200 having the semiconductor layer 210 can be cleaned, for example, in a standard SC1 and/or SC2 solution.

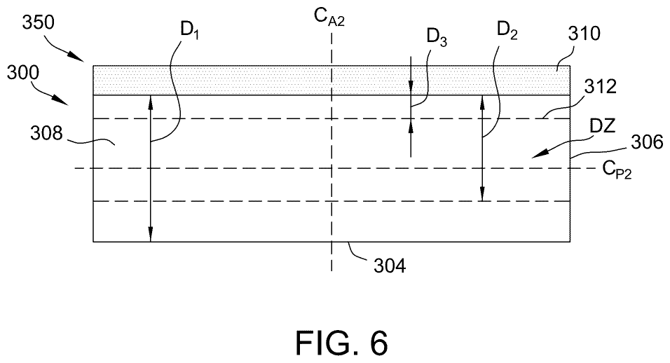

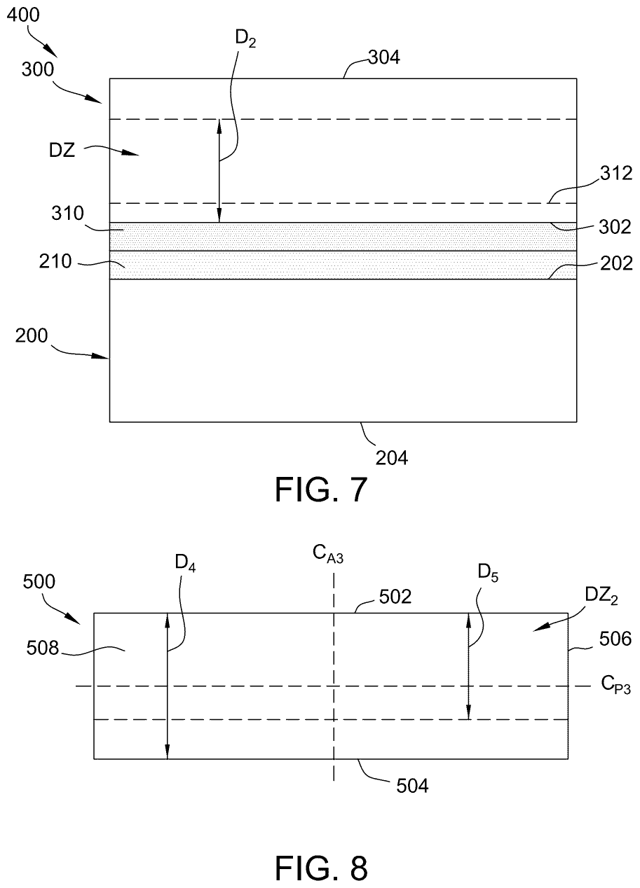

The handle substrate 200 having the semiconductor layer 210 is bonded to a donor structure 350 (shown in FIG. 6) to produce a bonded structure 400 (shown in FIG. 7) that is subsequently processed to produce the SOI structure 100. This sequence will be described further below.

FIG. 4 depicts an example single crystal silicon donor substrate 300 that is used to produce the device layer 108 in the SOI structure 100. The single crystal silicon donor substrate 300 may be sliced from a single crystal ingot grown in accordance with CZ or float zone growing methods. The donor substrate 300 may be polished and cleaned by suitable techniques and, in some examples, may have a mirror-polished surface finish that is free from surface defects, such as scratches and large particles.

In examples described herein, the donor substrate 300 is a silicon wafer sliced from a single crystal silicon ingot grown under conditions to meet or exceed the standards of Perfect Silicon™ (GlobalWafers Co., Ltd., Hsinchu, TW). Accordingly, the donor substrate 300 is characterized by a lack of agglomerated defects, DSODs (direct surface oxide defects), COPs, D-Defects, and I-defects (or A-defects). For example, perfect silicon donor substrates 300 may be characterized by non-detectable FPDs and DSODs, zero I-defects (A-defects), and less than 20 COPs at no more than 0.026 μm size. Methods for producing perfect silicon ingots and wafers sliced from these ingots are described, for example, in U.S. Pat. Nos. 11,408,090, issued Aug. 9, 2022; U.S. Pat. No. 11,313,049, issued Apr. 26, 2022; U.S. Pat. No. 11,111,597, issued Sep. 7, 2021; U.S. Pat. No. 11,111,596, issued Sep. 7, 2021; U.S. Pat. No. 11,085,128, issued Aug. 10, 2021; U.S. Pat. No. 8,673,248, issued Mar. 18, 2014; and U.S. Pat. No. 8,216,362, issued Jul. 10, 2012, the disclosures of each of which are hereby incorporated herein by reference in their entirety. Perfect silicon wafers may be obtained from commercial suppliers, such as GlobalWafers Co., Ltd., Taiwan.

The perfect silicon material that makes up the donor substrate 300 may have varying dominant intrinsic point defects, such as vacancies and/or interstitials, that occur in single crystal ingots grown by the CZ method. Whether the donor substrate 300 has vacancies or interstitials as the dominant intrinsic point defect has no impact on whether the donor substrate 300 is of perfect silicon quality, which is characterized as being free of agglomerated point defects, such as COPs, DSODs, and I-defects. The dominant intrinsic point defects of the donor substrate 300 may be the result of the growth conditions utilized for the single crystal ingot from which the donor substrate 300 is sliced. During growth of a single crystal silicon ingot by the CZ method, the ratio of the crystal pull rate (v) to the magnitude of the axial temperature gradient in the vicinity of the interface (G) is controlled to a critical v/G ratio at which agglomerated defects in the growing ingot are suppressed. The v/G ratio may vary within a range above and below the critical v/G ratio while still achieving acceptable control of agglomerated defects in the growing ingot to obtain perfect silicon quality. The dominant type of intrinsic point defects may depend on whether the v/G ratio is above or below the critical v/G ratio. Typically, the intrinsic point defects within the ingot will be predominantly vacancies where v/G is generally greater than the critical value, and the intrinsic point defects will be predominantly interstitials where v/G is generally less than the critical value. At some stages of crystal growth, a cross-section of the single crystal ingot (and thus a donor substrate 300 sliced from this region) may include bands dominated by different intrinsic point defect types. For example, some regions of the ingot grown under perfect silicon conditions may be characterized by a cross-section having a vacancy dominant point defect band that extends from a radial center of the cross-section to a radial length less than the radius of the ingot, and an interstitial dominant point defect band that surrounds the vacancy dominant point defect band and extends radially from the radial terminus of the vacancy dominant point defect band to the edge of the ingot. Other regions of the ingot may be characterized by a cross-section having vacancy dominant point defect perfect silicon in the center, surrounded by a band of interstitial dominant point defect perfect silicon, surrounded by another band of vacancy dominant point defect perfect silicon. These examples are merely for illustration and are not intended to be limiting upon the disclosure. The donor substrate 300 may be of any type of perfect silicon material, having vacancies as the dominant intrinsic point defects, interstitials as the dominant intrinsic point defects, or some combination thereof.

The donor substrate 300 may have any suitable interstitial oxygen concentration that is generally achieved by the CZ or float zone growing methods. For example, the donor substrate 300 may have an interstitial oxygen concentration of less than about 7.5×10¹⁷ atoms/cm³. The interstitial oxygen concentration of the donor substrate 300 may be greater than about 1×10¹⁷ atoms/cm³, greater than about 3×10¹⁷ atoms/cm³, greater than about 4.5×10¹⁷ atoms/cm³, or greater than about 6×10¹⁷ atoms/cm³. In various embodiments, the interstitial oxygen concentration of the donor substrate 300 is between about 1×10¹⁷ atoms/cm³ to about 7×10¹⁷ atoms/cm³, between about 1×10¹⁷ atoms/cm³ to about 6×10¹⁷ atoms/cm³, between about 1×10¹⁷ atoms/cm³ to about 4.5×10¹⁷ atoms/cm³, between about 3×10¹⁷ atoms/cm³ to about 7×10¹⁷ atoms/cm³, between about 3×10¹⁷ atoms/cm³ to about 6×10¹⁷ atoms/cm³, between about 3×10¹⁷ atoms/cm³ to about 4.5×10¹⁷ atoms/cm³, between about 4.5×10¹⁷ atoms/cm³ to about 7×10¹⁷ atoms/cm³, or between about 4.5×10¹⁷ atoms/cm³ to about 6×10¹⁷ atoms/cm³. The interstitial oxygen in the donor substrate 300 may be within a range that facilitates reducing the propensity of oxygen precipitates to grow in the donor substrate 300 during SOI processing. The range of acceptable interstitial oxygen concentrations for the donor substrate 300 may also provide a practical control window that is wider and/or higher than interstitial oxygen ranges typically accepted for donor substrates used to produce defect-free device layers in SOI structures. Moreover, the donor substrate 300 may have interstitial oxygen concentrations higher than those typically accepted for donor substrates 300 (e.g., greater than about 3×10¹⁷ atoms/cm³ or greater than about 4.5×10¹⁷ atoms/cm³), which may provide the ability to use donor substrates having a greater wafer strength.

The donor substrate 300 may also have a suitable nitrogen concentration. Nitrogen may be included as an impurity during growth of the perfect silicon ingot from which the donor substrate 300 is sliced to provide improved control point defect formation. Nitrogen doping may also provide a larger perfect silicon quality window for the crystal growth conditions. Nitrogen may also improve the strength of the donor substrate 300, particularly against slip in thermal SOI processing. The nitrogen concentration of the donor substrate 300 may be at least (i.e., greater than or equal to) about 1×10¹³ atoms/cm³, or at least about 3×10¹³ atoms/cm³. In some embodiments, the nitrogen concentration of the donor substrate 300 may be at least about 1×10¹³ atoms/cm³ and less than about 1×10¹⁵ atoms/cm³, at least about 1×10¹³ atoms/cm³ and less than about 5×10¹⁴ atoms/cm³, or at least about 5×10¹³ atoms/cm³ and less than about 5×10¹⁴ atoms/cm³. For example, the nitrogen concentration may be between about 3×10¹³ atoms/cm³ to about 1×10¹⁵ atoms/cm³, or between about 3×10¹³ atoms/cm³ to about 5×10¹⁴ atoms/cm³. Nitrogen concentration may be measured by secondary ion mass spectrometry (SIMS) (SEMI MF2139). In some embodiments, the donor substrate 300 may be substantially free of nitrogen (e.g., a nitrogen concentration of the donor substrate 300 may be below a detectable limit).

In some embodiments, the donor substrate 300 may include a p-type or an n-type dopant. Suitable p-type dopants include boron, gallium, or combinations thereof. Suitable n-type dopants include phosphorus, antimony, arsenic, or combinations thereof. The dopant concentration in the donor substrate 300 may be selected based on the desired resistivity of the donor substrate.

The donor substrate 300, similar to the handle substrate 200, includes two major, generally parallel surfaces. One of the surfaces is a front surface 302 (also referred to as a front donor substrate surface, a front donor wafer surface, or a front donor surface), and the other surface is a back surface 304 of the substrate (also referred to as a back donor substrate surface, a back donor wafer surface, or a back donor surface). The donor substrate 300 also includes a circumferential edge 306 joining the front surface 302 and the back surface 304, a bulk region 308 between the front surface 302 and the back surface 304, and a central plane C_{P2} between the front surface 302 and the back surface 304. The donor substrate 300 additionally includes an imaginary central axis C_{A2} substantially perpendicular to the central plane C_{P2}.

A radial length of the donor substrate 300 is measured as the distance between the central axis C_{A2} and the circumferential edge 306. A diameter of the donor substrate 300 is measured across the circumferential edge 306. The donor substrate 300 may have any suitable nominal diameter, such as a diameter of at least about 150 mm, at least about 200 mm, at least about 300 mm, or at least about 450 mm. The donor substrate 300 also has a thickness D₁ measured as a distance between the front surface 302 and the back surface 304. The donor substrate 300 may have any suitable thickness D₁. For example, the thickness D₁ of the donor substrate 300 may be between about 100 μm to about 1500 μm, such as between 250 μm to about 1500 μm, between about 300 μm and about 1000 μm, or between about 500 μm to about 1000 μm. The donor substrate 300, like the handle substrate 200, may have some total thickness variation (TTV), warp, and/or bow, such that the midpoint between every point on the front surface 302 and every point on the back surface 304 may not precisely fall within a plane. As a practical matter, however, the TTV, warp, and bow are typically so slight that to a close approximation the midpoints can be said to fall within the imaginary central plane C_{P2} which is approximately equidistant between the front surface 302 and the back surface 304.

The donor substrate 300 also includes a denuded zone DZ that extends from the front donor substrate surface 302 toward the back donor substrate surface 304. The denuded zone DZ is a region in the donor substrate 300 that is characterized by non-detectable oxygen precipitates measured by LST. The denuded zone DZ may be characterized by a lack of bulk micro defects (BMDs), that is, BMDs within a BMD density range of less than about 1×10⁹ cm⁻³, less than about 1×10⁸ cm⁻³, less than about 1×10⁷ cm⁻³, or less than about 5×10⁶ cm⁻³, measured by LST. Example LST apparatus for detecting BMD density include the LST-2500HD tool available from Semilab and the MO441 tool available from Raytex Corporation. The denuded zone DZ may also be referred to herein as an oxygen precipitate free zone (PFZ).

The denuded zone DZ extends a denuded zone depth D₂ that is a suitable distance to enable multiple device layers 108 to be transferred from the donor substrate 300. The denuded zone depth D₂ may be at least (i.e., greater than or equal to) about 25 μm, at least about 50 μm, at least about 100 μm, at least about 150 μm, at least about 200 μm, at least about 250 μm, or at least about 300 μm. The denuded zone depth D₂ may, in some embodiments, be approximately equal to the donor substrate thickness D₁. Example LST apparatus for detecting the denuded zone depth D₂ include the LST-2500HD tool available from Semilab and the MO441 tool available from Raytex Corporation.

The denuded zone depth D₂ may also be a suitable percentage of the thickness D₁ of the donor substrate 300. As described above, the thickness of the donor substrate 300 may be any suitable thickness D₁, for example, between about 100 μm to about 1500 μm, such as between 250 μm to about 1500 μm, between about 300 μm and about 1000 μm, or between about 500 μm to about 1000 μm. The denuded zone depth D₂ may be at least (i.e., greater than or equal to) about 5% of the donor substrate thickness D₁, such as at least about 10% of the donor substrate thickness D₁, at least 25% of the donor substrate thickness D₁, or at least 50% of the donor substrate thickness D₁. In some examples, the denuded zone depth D₂ may be at least 75% of the donor substrate thickness D₁. In some examples, the denuded zone DZ may extend the entire thickness of the donor substrate 300, such that the denuded zone depth D₂ is equal to (or 100% of) the donor substrate thickness D₁.

In example embodiments, the denuded zone DZ is formed in the donor substrate 300 by performing an ultra-high temperature rapid thermal process (UHT RTP) on the donor substrate. The UHT RTP is performed in an oxidizing gas atmosphere at a temperature and for a duration sufficient to form the denuded zone DZ, which is free of oxygen precipitates, at a suitable denude zone depth D₂ as well as maintain low levels of COPs in the donor substrate 300. Example UHT RTP processes in accordance with the present disclosure are generally described, for example, in U.S. Pat. Nos. 11,162,191, issued Nov. 2, 2021, U.S. Pat. No. 8,476,149, issued Jul. 2, 2013, and U.S. Pat. No. 7,977,219, issued Jul. 12, 2011, the disclosures of each of which are hereby incorporated herein by reference in their entirety. Additional description on example UHT RTP processes is provided in Haruo Sudo et al., ECS J. of Solid State Science and Tech., 8(1) P35-P40 (2019) and Susumu Maeda et al., J. Applied Physics 123, 161591 (2018), the disclosures of each of which are hereby incorporated herein by reference in their entirety.

Example apparatus (or RTP apparatus) for performing the UHT RTP on the donor substrate 300 are described in U.S. Pat. Nos. 8,476,149 and 7,977,219. An example RTP apparatus includes a reaction chamber in which the donor substrate is positioned and into which the oxidizing gas atmosphere is introduced. The donor substrate 300 is loaded into the reaction chamber and placed on a susceptor which supports the donor substrate. The oxidizing gas atmosphere is introduced via a gas inlet. The apparatus also includes heating elements (e.g., radiant light heating lamps, such as halogen lamps) that are disposed adjacent or within the reaction chamber and heat the donor substrate 300. The reaction chamber may be enclosed by upper and lower walls made of a suitable material (e.g., quartz) that enables radiant heating light from the heating elements located outside the reaction chamber proximate the walls to pass therethrough and heat the donor substrate 300. The heating elements rapidly heat the donor substrate 300 in the reaction chamber. Temperature control in the reaction chamber may be facilitated by measuring an average temperature along a surface, in a diameter direction, of the donor substrate 300 supported by the susceptor (e.g., the back surface 304) using temperature sensors (e.g., radiation thermometers) positioned below the susceptor and controlling the heating elements based on the measured temperature.

In an example UHT RTP, the donor substrate 300 is positioned in the reaction chamber of the RTP apparatus and the temperature within the reaction chamber is rapidly increased. An inert gas (e.g., argon, Ar) is introduced into the reaction chamber as the temperature is rapidly increased. A relatively small amount of an oxidizing gas (e.g., oxygen gas, O₂) may also be introduced at this stage. For example, O₂ gas may be introduced at from about 0.01% to about 1% by volume with the inert gas into the reaction chamber as the temperature is rapidly increased in the reaction chamber.

When the donor substrate 300 is positioned in the reaction chamber, the temperature within the reaction chamber may be, for example, between about 400° C. to about 600° C., such as about 500°. The inert gas, optionally with the relatively small amount of the oxidizing gas, is introduced as the temperature is rapidly increased to a rapid thermal processing (RTP) temperature at which the UHT RTP is performed. In example embodiments, the RTP temperature is at least (i.e., greater than or equal to) 1275° C., such as at least 1300° C. The RTP temperature may also be lower than the melting point of silicon (e.g., about 1414° C.). For example, the RTP temperature may be between about 1275° C. to about 1400° C., between about 1300° C. to about 1400° C., between about 1300° C. to about 1380° C., between about 1300° C. to about 1350° C., between about 1350° C. to about 1400° C., between about 1350° C. to about 1380° C., between about 1275° C. to about 1380° C., between about 1275° C. to about 1350° C., or between about 1275° C. to about 1300° C. In various embodiments, the RTP temperature of about 1275° C., about 1300° C., about 1325° C., about 1350° C., about 1375° C., or about 1400° C.

The temperature within the reaction chamber may be rapidly increased to the RTP temperature for the UHT RTP at a heating rate of between about 10° C./second (° C./s) to about 150° C./s. For example, the heating rate at which the temperature in the reaction chamber is increased to the RTP temperature may be between about 25° C./s to about 150° C./s, between about 50° C./s to about 150° C./s, between about 75° C./s to about 150° C./s, between about 100° C./s to about 150° C./s, between about 125° C./s to about 150° C./s, between about 10° C./s to about 125° C./s, between about 10° C./s to about 100° C./s, between about 10° C./s to about 75° C./s, between about 10° C./s to about 50° C./s, or between about 10° C./s to about 25° C./s. In various examples, the heating rate at which the temperature in the reaction chamber is increased to the RTP temperature may be about 10° C./s, about 25° C./s, about 50° C./s, about 75° C./s, about 100° C./s, about 125° C./s, or about 150° C./s.

When the temperature within the reaction chamber reaches the RTP temperature, the oxidizing gas atmosphere is introduced into the reaction chamber to initiate the UHT RTP. Prior to introducing the oxidizing gas atmosphere, flow of the inert gas (e.g., Ar) and optionally the relatively small amount (e.g., from about 0.01% to about 1% by volume) of the oxidizing gas (e.g., O₂ gas) may continue for a residence time period. In some examples, the flow of the inert gas and optional oxidizing gas mixture may continue at the RTP temperature for a residence time period of between about one second(s) to about 60 seconds (one minute). After the residence time period, the flow of the inert gas and the optional oxidizing gas mixture is discontinued and the oxidizing atmosphere is introduced into the reaction chamber at the RTP temperature to initiate the UHT RTP. In some examples, after the residence time period at the RTP temperature elapses, intermediate cooling may occur prior to initiating the UHT RPT (i.e., prior to introducing the oxidizing gas atmosphere). After the optional intermediate cooling, the temperature in the reaction chamber is again rapidly increased to the RTP temperature and the oxidizing gas atmosphere is introduced into the reaction chamber. In some examples, the flow of the inert gas and the optional oxidizing gas mixture is immediately discontinued once the temperature within the reaction chamber reaches the RTP temperature for the UHT RTP and the oxidizing atmosphere is then introduced into the reaction chamber to initiate the UHT RTP.

The oxidizing gas atmosphere that is introduced into the reaction for the UHT RTP includes oxygen (O₂) gas. The O₂ gas is present in the oxidizing gas atmosphere in a sufficient amount to facilitate forming the denuded zone DZ by the UHT RTP. The oxidizing gas atmosphere may include O₂ gas in an amount of at least (i.e., equal to or greater than) about 20% by volume, such as at least about 50% by volume, or at least about 75% by volume. In various embodiments, the oxidizing gas atmosphere includes O₂ gas in an amount of between about 20% by volume to about 100% by volume, such as between about 50% by volume to about 100% by volume, or between about 75% by volume to about 100% by volume. For example, in some embodiments, the oxidizing gas atmosphere for the UHT RTP includes O₂ gas in an amount of about 100% by volume.

As described above, the RTP temperature for the UHT RTP is at least (i.e., greater than or equal to) 1275° C., or at least 1300° C., such as a temperature of between about 1275° C. to about 1400° C. or between about 1300° C. to about 1400° C. The UHT RTP includes maintaining the donor substrate 300 at the RTP temperature and in the oxidizing gas atmosphere for a sufficient duration to facilitate forming the denuded zone DZ. For example, the duration of the UHT RTP may be at least (i.e., greater than or equal to) about 15 seconds, such as at least about 30 seconds. In some embodiments, the duration of the UHT RTP may be greater than about 30 seconds, such as at least about 45 seconds, at least about one minute, at least about two minutes, at least about three minutes, at least about four minutes, or at least about five minutes. In some embodiments, the duration of the UHT RTP may be greater than five minutes, such as up to about ten minutes. In various embodiments, the UHT RTP is performed for a duration of between about one second to about ten minutes, such as between about one second to about five minutes, between about one second to about four minutes, between about one second to about three minutes, between about one second to about two minutes, between about one second to about one minute, between about one second to about 45 seconds, between about one second to about 30 seconds, between about one second to about 15 seconds, between about 15 seconds to about five minutes, between about 15 seconds to about one minute, between about 15 seconds to about 45 seconds, between about 15 seconds to about 30 seconds, between about 30 seconds to about five minutes, between about 30 seconds to about one minute, between about 30 seconds to about 45 seconds, between about 45 seconds to about five minutes, between about 45 seconds to about one minute, between about one minute to about ten minutes, between about one minute to about five minutes, or between about five minutes to about ten minutes. In certain embodiments, the UHT RTP is performed for a duration of about one second, about five seconds, about ten seconds, about 15 seconds, about 20 seconds, about 25 seconds, about 30 seconds, about 35 seconds, about 40 seconds, about 45 seconds, about 50 seconds, about 55 seconds, about one minute, about two minutes, about three minutes, about four minutes, about five minutes, about six minutes, about seven minutes, about eight minutes, about nine minutes, or about ten minutes.

The duration of the UHT RTP may depend on the RTP temperature. For example, the duration of the UHT RTP may decrease as the RTP temperature increases. Where the RTP temperature is less than 1300° C., such as between about 1275° C. to about 1300° C., or about or about 1275° C., the duration of the UHT RTP may be at least (i.e., greater than or equal) to one minute. For example, in some embodiments, the RTP temperature is between about 1275° C. to about 1300° C., or about 1275° C., and the duration of the UHT RTP is between about one minute to about ten minutes, such as between about one minutes to about five minutes, between about five minutes to about ten minutes, about one minute, about two minutes, about three minutes, about four minutes, about five minutes, about six minutes, about seven minutes, about eight minutes, about nine minutes, or about ten minutes. In some embodiments, where the RTP temperature is at least (i.e., greater than or equal to) 1300° C., such as a temperature of between about 1300° C. to about 1400° C., or about 1300° C., the duration of the UHT RTP may be one minute or shorter than one minute. For example, in some embodiments, the RTP temperature is between about 1300° C. to about 1400° C., or about 1300° C., and the duration of the UHT RTP is between about one second to about one minute, such as about one second, about five seconds, about ten seconds, about 15 seconds, about 20 seconds, about 25 seconds, about 30 seconds, about 35 seconds, about 40 seconds, about 45 seconds, about 50 seconds, about 55 seconds, or about one minute.

After performing the UHT RTP on the donor substrate 300, a rapid cooling process may be performed in the reaction chamber. During the rapid cooling process, the oxidizing gas atmosphere may continue to flow into the reaction chamber. The rapid cooling process may be performed to reduce the temperature of the donor substrate 300 within the reaction chamber to a suitable temperature for post-process handling. For example, the rapid cooling process may be performed to reduce the temperature of the donor substrate 300 to a temperature of between about 400° C. to about 600° C., such as about 500°. The rapid cooling process may include cooling the donor substrate 300 at a desired cooling rate. The cooling rate may be, for example, at least (i.e., greater than or equal to) about 10° C./s, such as at least about 25° C./s, at least about 50° C./s, at least about 75° C./s, or at least about 100° C./s. In various embodiments, the cooling rate may be between about 10° C./s to about 150° C./s, between about 25° C./s to about 150° C./s, between about 50° C./s to about 150° C./s, between about 75° C./s to about 150° C./s, between about 100° C./s to about 150° C./s, between about 125° C./s to about 150° C./s, between about 10° C./s to about 125° C./s, between about 10° C./s to about 100° C./s, between about 10° C./s to about 75° C./s, between about 10° C./s to about 50° C./s, or between about 10° C./s to about 25° C./s. In various examples, the heating rate at which the temperature in the reaction chamber is increased to the RTP temperature may be about 10° C./s, about 25° C./s, about 50° C./s, about 75° C./s, about 100° C./s, about 125° C./s, or about 150° C./s.

The UHT RTP and subsequent rapid cooling process are performed at conditions sufficient to produce the denuded zone DZ in the donor substrate 300 at the denuded zone depth D₂. As described above, the denuded zone DZ is a region in the donor substrate 300 that is characterized by non-detectable oxygen precipitates measured by LST. The denuded zone DZ may be characterized by a lack of bulk micro defects (BMDs), that is, BMDs within a BMD density range of less than about 1×10⁹ cm⁻³, less than about 1×10⁸ cm⁻³, less than about 1×10⁷ cm⁻³, or less than about 5×10⁶ cm⁻³, measured by LST. The denuded zone DZ may also be characterized by non-detectable FPDs (flow pattern defects measured by the Secco-etching technique) and DSODs (direct surface oxide defect particle count after electric breakdown), and zero I-defects (A-defects) measured by the Secco-etching technique, as well as less than 20 COPs at no more than 0.026 μm size. During the UHT RTP, grown-in defects (e.g., BMDs and/or COPs) may be eliminated in the donor substrate 300 to at least the denuded zone depth D₂ by oxygen from the oxidizing gas atmosphere that rapidly dissolves into the donor substrate as well as a supersaturation of interstitial silicon in the denuded zone DZ resulting from the UHT RTP. As the donor substrate 300 is rapidly heated to the RTP temperature, a thin surface oxide film (e.g., a silicon dioxide, SiO₂, film) may be formed on an exposed surface of the donor substrate. Oxide films (e.g., silicon dioxide, SiO₂, films) may also form on the inner walls of void defects (e.g., COPs) at the exposed surface and/or within the bulk region 308 of the donor substrate 300 as the donor substrate is rapidly heated to the RTP temperature. At the RTP temperature, and in the presence of the oxidizing gas atmosphere, oxygen rapidly dissolves in the donor substrate 300 and interstitial silicon is also introduced into the donor substrate. The inner-wall oxide films of any void defects (e.g., COPs) that exist in the donor substrate 300 disappear as the oxygen dissolves into the donor substrate and the resulting interstitial silicon fills the void defects during the UHT RTP, thus eliminating the void defects and forming the denuded zone DZ. The denuded zone DZ has a relatively high oxygen concentration, attributed to the amount of interstitial oxygen in the donor substrate 300 and oxygen that dissolves into the donor substrate during the UHT RTP, which facilitates limiting or preventing dislocations from generating during subsequent SOI processing performed on the donor substrate. The supersaturation of the interstitial silicon in the denuded zone DZ facilitates limiting or preventing the oxygen in the denuded zone from forming oxygen precipitates during subsequent SOI processing.

In some embodiments, after the UHT RTP is performed to produce the denuded zone DZ, the donor substrate 300 may be subjected to a polishing operation, such as double-side polishing or single-side polishing, to planarize the generally parallel front and back surfaces 302 and/or 304 of the donor substrate 300. For example, a CMP operation may be performed on the front surface 302 of the donor substrate 300 after the UHT RTP. In some embodiments, the front surface 302 of the donor substrate 300 may include an oxide film or surface defects (e.g., COPs) that remain after the UHT RTP. A polishing operation may suitably be performed after the UHT RTP to expose the front surface 302 of the donor substrate 300 for subsequent SOI processing (e.g., for forming a dielectric layer on the front surface 302) and remove any undesired remaining material and/or defects. One or both of the surfaces 302 and 304 may additionally and/or alternatively be cleaned by known techniques after the UHT RTP to remove any contaminants or remaining material. Suitably, the denuded zone DZ maintains a suitable denuded zone depth D₂ in the donor substrate 300 after the polishing and/or cleaning operations performed after the UHT RTP.

Referring now to FIG. 5, after the denuded zone DZ is formed in the donor substrate 300 and the front surface 302 is optionally polished and/or cleaned following the UHT RTP, a dielectric layer 310 is formed on the front surface 302 of the donor substrate to produce a donor structure 350. The donor structure 350 includes the donor substrate 300 having the denuded zone DZ and the dielectric layer 310 formed on the front surface 302 of the donor substrate. The dielectric layer 310 forms the dielectric layer 106 in the SOI structure 100 shown in FIG. 1. The material used for the dielectric layer 310 may vary depending on the intended application of the donor substrate 300 (e.g., the desired end use of the SOI structure 100). In some examples, the dielectric layer 310 may include an oxide or a nitride layer. For example, the dielectric layer 310 may include a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof. The dielectric layer 310 may have any suitable thickness. For example, the thickness of the dielectric layer 310 may be at least (i.e., greater than or equal to) 10 nanometers (nm), such as between about 10 nm to about 10 μm, between about 10 nm to about 5 μm, between about 10 nm to about 1 μm, or between about 10 nm to about 800 nm. The thickness of the dielectric layer 106 may be less than about 500 nm, such as less than about 300 nm, less than about 200 nm, less than about 150, or less than about 100 nm. In some embodiments, the thickness of the dielectric layer 106 may be less than about 10 nm.

In some embodiments, the dielectric layer 310 may include an oxide layer (e.g., silicon dioxide or silicon oxynitride) or a nitride layer (e.g., silicon nitride) that is formed by a suitable layer forming technique performed on the front surface 302 of the donor substrate 300. In some embodiments, the dielectric layer 310 may be formed on the front surface 302 may be accomplished by thermal oxidation or nitriding, CVD oxide or nitride deposition, and/or atomic layer deposition. In some embodiments, the dielectric layer 310 may be formed by thermally oxidizing or nitriding the donor substrate 300 in a furnace such as an ASM A400 or an ASM A412. During such processes to form the dielectric layer 310, the temperature may range from 750° C. to 1200° C. in an oxidizing or nitriding ambient. An oxidizing ambient atmosphere may be a mixture of inert gas, such as argon (Ar) or nitrogen gas (N₂), and O₂ gas. The O₂ gas content in the oxidizing ambient during thermal oxidation may vary from 1 to 10 percent, by volume, or higher. In some embodiments, the oxidizing ambient may be up to 100% O₂ by volume (a “dry oxidation”). In some embodiments, the ambient may be an oxidizing and nitriding ambient that includes a mixture of O₂ gas and a nitriding gas, such as ammonia gas, which may be suitable for depositing silicon oxynitride. In some embodiments, the ambient may include a mixture of inert gas, such as Ar or N₂, and oxidizing gases, such as O₂ and water vapor (a “wet oxidation”). In some embodiments, the ambient may include a mixture of inert gas, such as Ar or N₂, and oxidizing gas, such as O₂ and water vapor (a “wet oxidation”), and a nitriding gas, such as ammonia. In some embodiments, the nitriding ambient may comprise a mixture of inert gas, such as Ar or N₂, and a nitriding gas, such as ammonia, which is suitable for depositing silicon nitride.

The device layer 108 in the SOI structure 100 shown in FIG. 1 is derived from the donor substrate 300. In particular, the donor structure 350 is brought into intimate contact with and bonded to the handle substrate 200 to produce a bonded structure 400 as shown in FIG. 7, and a portion of the denuded zone DZ of the donor substrate 300 is removed from the bonded structure to transfer the device layer 108. The device layer 108 may be transferred from the donor substrate 300 by wafer thinning techniques such as etching or by cleaving.

Referring to FIG. 6, to enable transfer of the device layer 108 from to donor substrate 300 by cleaving, a cleave plane 312 may be formed in the donor substrate 300. The cleave plane 312 may be formed in the donor substrate 200 by known ion implantation techniques. Ion implantation may be carried out in a commercially available instrument, such as an Applied Materials Quantum H. Implanted ions include helium (He), or hydrogen (H and/or H₂), or combinations thereof. Ion implantation is carried out at a density and duration sufficient to form the cleave plane 312 in the donor substrate 300. Implant density may range from about 10¹² ions/cm² to about 10¹⁷ ions/cm², such as from about 10¹⁴ ions/cm² to about 10¹⁷ ions/cm². Implant energies may range from about 1 keV to about 3,000 keV, such as from about 10 keV to about 3,000 keV. In some embodiments it may be desirable to subject the donor substrate 300 to a cleaning operation after the implant, for example, a Piranha clean followed by a deionized water rinse and cleaning using a SC1 and/or SC2 solution. The donor substrate 300 having the cleave plane may also be annealed at a temperature sufficient to thermally activate the cleave plane 312. An example of a suitable annealing tool is a box furnace, such as a Blue M model. The ion-implanted donor substrate 300 may be annealed at a temperature of, for example, from about 200° C. to about 350° C., and for a duration of, for example, from about 2 hours to about 10 hours. The donor substrate 300 may be thermally annealed at any temperature and duration sufficient to thermally activate the cleave plane 312. The cleaning operations performed on the ion-implanted donor substrate 300 may be performed before and/or after the thermal anneal to activate the cleave plane 312.

The cleave plane 312 extends a depth D₃ into the bulk region 308 of the donor substrate 300, measured from the front surface 302. The device layer 108 is transferred from a portion of the denuded zone DZ between the cleave plane 312 and the front surface 302, such that the device layer 108 transferred from the donor substrate 300 is free of surface and bulk defects (e.g., oxygen precipitates and COPs). The depth D₃ of the cleave plane 312 may vary based on the desired thickness of the device layer 108 in the SOI structure 100. In general, the depth D₃ of the cleave plane 312 is shallower than the denuded zone depth D₂ to enable multiple device layers 108 to be transferred from the denuded zone DZ of the donor substrate 300. As described above, the denuded zone depth D₂ may be at least (i.e., greater than or equal to) about 25 μm, at least about 50 μm, at least about 100 μm, at least about 150 μm, at least about 200 μm, at least about 250 μm, or at least about 300 μm. The depth D₃ of the cleave plane 312 may be at least three times shallower than the denuded zone depth D₂, such as at least five times shallower, at least ten times shallower, at least 15 times shallower, or at least 20 times shallower than the denuded zone depth D₂. For example, the depth D₃ of the cleave plane 312 may be shallower than about 3 μm, such as shallower than about 1 μm, shallower than about 500 nm, or shallower than about 300 nm. As described above, the thickness of the transferred device layer 108 may be between about 10 nm to about 3 μm, such as between about 10 nm to about 1 μm, between about 100 nm to about 1 μm, between about 100 nm to about 500 nm, between about 500 nm to about 1 μm, between about 100 nm to about 300 nm, between about 200 nm to about 500 nm, between about 300 nm to about 700 nm, or between about 400 nm to about 600 nm. In some embodiments, the depth D₃ of the cleave plane 312 may be approximately equal to the thickness of the device layer 108. In other embodiments, the depth D₃ of the cleave plane 312 may be slightly larger than the thickness of the device layer 108 to compensate for material losses during layer transfer and/or post-transfer smoothing of the device layer 108.

Referring to FIG. 7, the exposed surface of the dielectric layer 310, opposite the front surface 302 of the donor substrate 300, and the exposed surface of the semiconductor layer 210, opposite of the front surface 202 of the handle substrate 200, are brought into intimate contact to thereby form the bonded structure 400. The bonded structure 400 includes donor substrate 300, the dielectric layer 310 formed on the front surface 302 of the donor substrate, the semiconductor layer 210 formed on the front surface 202 of the handle substrate 200 and in interfacial contact with the dielectric layer 310, and the handle substrate 200. To make the exposed surfaces of the dielectric layer 310 and the semiconductor layer 210 hydrophilic and amenable to bonding, plasma surface activation (e.g., oxygen plasma and/or nitrogen plasma surface activation) may be performed on one or both of the dielectric layer and the semiconductor layer using any suitable commercially available plasma activation tool, such as those available from EV Group, e.g., EVG® 810LT Low Temp Plasma Activation System. Additionally and/or alternatively, the bonded structure 400 may be subjected to an anneal to strengthen the bond between the semiconductor layer 210 and the dielectric layer 310. For example, the bonded structure 400 may be annealed in a box furnace, such as a Blue M model, at a temperature and for a duration sufficient to solidify the bond between the semiconductor layer 210 and the dielectric layer 310. In some embodiments, the bonded structure 400 is annealed at a temperature of from about 200° C. to about 350° C., and for a duration of from about 0.5 hours to about 10 hour. Thermal annealing of the bonded structure 400 may also contribute to thermally activating the cleave plane 312.

The bonded structure 400 is cleaved to produce the SOI structure 100 shown in FIG. 1. Cleaving may occur according to techniques known in the art. In some embodiments, the bonded structure 400 may be placed in a cleave station affixed to stationary suction cups on one side (e.g., on one of the back surfaces 204, 304) and affixed by additional suction cups on a hinged arm on the other side (e.g., on another one of the back surfaces 204, 304). A crack is initiated near the suction cup attachment and the movable arm pivots about the hinge cleaving the donor substrate 300 apart. Cleaving removes a portion of the donor substrate 300, thereby transferring the semiconductor device layer 108 on the SOI structure 100.

After cleaving, the SOI structure 100 may be subjected to a high temperature anneal. An example of a suitable tool might be a vertical furnace, such as an ASM A400 or an ASM A412. In some embodiments, the SOI structure 100 is annealed at a temperature of from about 950° C. to about 1200° C., and for a duration of from about 15 minutes to about 10 hours. The thermal anneal of the SOI structure 100 may, in some embodiments, be performed in an anneal atmosphere that includes at least one of argon gas, hydrogen gas, and helium gas, or a combination of two or more of these gases. The thermal anneal may strengthen the bonds between adjacent layers of the SOI structure 100 (e.g., the bond between the transferred device layer 108 and the dielectric layer 106). The thermal anneal may additionally and/or alternatively function to smooth the exposed surfaces of the SOI structure (e.g., smooth the exposed surface of the transferred device layer 108).

In some embodiments, the SOI structure 100 may be subjected to a polishing operation to planarize one or both of the exposed surfaces of the SOI structure (e.g., the exposed surface of the transferred device layer 108). The polishing operation may be performed in addition to (e.g., before and/or after) or in the alternative to the high temperature thermal anneal. For example, a CMP operation may be performed to smooth the exposed surface of the transferred device layer 108. In some embodiments, a CMP operation is performed on the transferred device layer 108, followed by the high temperature thermal anneal performed on the SOI structure 100.

After the cleave and, optionally, the high temperature anneal and/or polishing operation, the transferred device layer 108 of the SOI structure 100 may be subjected to an additional smoothing process to reduce the roughness of the transferred device layer 108 in the SOI structure 100 and/or remove any implant damage of the device layer that was not compensated for by any previous smoothing processes (e.g., in the high temperature thermal anneal and/or the polishing operation). The additional smoothing process may also be referred to as a “non-contact smoothing process,” an “epitaxial smoothing process,” or “epi-smoothing process.” Example epi-smoothing processes are described, for example, in U.S. Pat. No. 9,202,711, issued Dec. 1, 2015, the disclosure of which is hereby incorporated by reference herein in its entirety. The epi-smoothing process is typically performed in a suitable reactor (e.g., an epitaxial deposition reactor) that is operable to heat the SOI structure 100 in a reaction chamber and introduce etchant gases into the reaction chamber that perform work on (e.g., etch) the transferred device layer 108 to produce a smoothed surface. For example, the epi-smoothing process may include positioning the SOI structure 100 in an epi-reactor chamber, heating the chamber to a temperature between 900° C. and 1050° C., introducing gaseous etchant (e.g., hydrogen chloride, HCl, or chlorine and hydrogen gas, H₂) into the chamber, and maintaining temperature and flow of the gaseous etchant for a suitable duration to achieve a desired surface roughness of the transferred device layer 108. In some embodiments, the root mean square (RMS) surface roughness of the SOI structure 100 following epi-smoothing is below about 0.2 nm as measured with scan sizes of about 1 μm×about 1 μm to about 30 μm×about 30 μm.

As described above, the transferred device layer 108 is suitably characterized by non-detectable FPDs and DSODs, zero I-defects (A-defects), less than 20 COPs at no more than 0.026 μm size, as well as non-detectable oxygen precipitates and a lack of BMDs. Advantageously, the lack of grown-in surface and bulk defects in the transferred device layer 108 may enhance the efficacy of the epi-smoothing process. Any surface or bulk defect in the transferred device layer 108 such as a COP or oxygen precipitates may otherwise act as a mask to the gaseous etchant, creating defects that will affect device performance. As such, the provision of the transferred device layer 108 characterized as described herein reduces post epi-smoothing defectivity and promotes the smoothness of the layer 108 in the SOI structure 100.

Following any planarization processes performed on the SOI structure 100, the SOI structure may then be subjected to further processing based on a desired end use of the SOI structure. For example, an epitaxial layer may be deposited on the transferred device layer 108. A deposited epitaxial layer may comprise substantially the same electrical characteristics as the underlying device layer. Alternatively, the epitaxial layer may comprise different electrical characteristics as the underlying device layer. An epitaxial layer may comprise a material selected from the group consisting of silicon, silicon carbide, silicon germanium, gallium arsenide, gallium nitride, indium phosphide, indium gallium arsenide, germanium, and combinations thereof. Depending upon the desired properties of the final device, the epitaxial layer may comprise a dopant, such as a p-type dopant (e.g., boron, gallium, aluminum, and/or indium) and/or an n-type dopant (e.g., phosphorus, antimony, and/or arsenic). In embodiments where epi-smoothing is performed on the SOI structure 100, the SOI structure may remain in the reactor and be subjected to an epi-deposition process in the same reactor, or the epitaxial layer may be deposited on the device layer 108 in a separate reactor.

Referring to FIG. 8, after cleaving the bonded structure 400, a second donor substrate 500 is formed from the remaining portion of the donor substrate 300 after the transfer of the device layer 108 on the SOI structure 100. The second donor substrate 500 may also be referred to herein as a reclaimed donor substrate 500. The second donor substrate 500 includes a front surface 502 and a back surface 502 which are generally parallel, a circumferential edge 506 joining the front surface 502 and the back surface 504, a bulk region 508 between the front surface 502 and the back surface 504, and a central plane C_{P3} between the front surface 502 and the back surface 504. The donor substrate 500 additionally includes an imaginary central axis C_{A3} substantially perpendicular to the central plane C_{P3}.

Like the donor substrate 300 from which it is formed, in example embodiments, the second donor substrate 500 is a perfect silicon wafer characterized by non-detectable FPDs and DSODs, zero I-defects (A-defects), and less than 20 COPs at no more than 0.026 μm size. The second donor substrate 500 also includes a second denuded zone DZ₂ that extends from the front surface 502 toward the back surface 504. The second denuded zone DZ₂ is the remaining portion of the denuded zone DZ following transfer of the device layer 108 from the donor substrate 300. The second denuded zone DZ₂, like the denuded zone DZ of the donor substrate 300 described above, is a region in the second donor substrate 500 that is characterized by non-detectable oxygen precipitates measured by LST, and may be characterized by a lack of bulk micro defects (BMDs), that is, BMDs within a BMD density range of less than about 1×10⁹ cm⁻³, less than about 1×10⁸ cm⁻³, less than about 1×10⁷ cm⁻³, or less than about 5×10⁶ cm⁻³, measured by LST. The second denuded zone DZ₂ may also be referred to herein as an oxygen precipitate free zone (PFZ).

As described above, the donor substrate 300 has the thickness D₁ and the denuded zone DZ extends the denuded zone depth D₂ that is a suitable distance to enable multiple device layers 108 to be transferred from the donor substrate 300. After layer transfer of the device layer 108, the second donor substrate 500 has a thickness D₄ and includes the second denuded zone DZ₂ that extends a second denuded zone depth D₅. The thickness D₄ of the second donor substrate 500 may be approximately equal to the thickness D₁ of the donor substrate 300 less the depth D₃ of the cleave plane 312. Similarly, the second denuded zone depth D₅ may be approximately equal to the denuded zone depth D₂ of the denuded zone DZ less the depth D₃ of the cleave plane 312. The thickness D₄ may be slightly smaller than the thickness D₁ of the donor substrate 300 less the depth D₃ of the cleave plane 312 and the second denuded zone depth D₅ may be slightly smaller than the denuded zone depth D₂ less the depth D₃ of the cleave plane 312. Such may be the case where some material is removed from the second donor substrate 500 after cleave and layer transfer. For example, the front surface 502 of the donor substrate 500 may be planarized after layer transfer of the device layer 108 to reduce the roughness of the front surface after cleave and/or remove any implant damage. Suitable planarization techniques for the second donor substrate 500 include any of those described above, e.g., polishing, thermal anneal, and/or epi-smoothing. Thus, in various embodiments, the thickness D₄ may be smaller than the thickness D₁ of the donor substrate 300 at least by the depth D₃ of the cleave plane 312 and/or the thickness of the transferred device layer 108, and the second denuded zone depth D₅ may be smaller than the denuded zone depth D₂ at least by the depth D₃ of the cleave plane 312 and/or the thickness of the transferred device layer 108.

The second donor substrate 500 that includes the second denuded zone DZ₂ at the second denuded zone depth D₅ is reclaimable for the production of a subsequent SOI structure (e.g., a second SOI structure 100). In particular, the second denuded zone DZ₂ that exists in the remaining second donor substrate 500 extends to a sufficient depth D₅ whereby a second layer transfer operation may be performed using the second donor substrate for producing another transferred device layer 108 characterized by a lack of grown-in surface and bulk defects as described above. In example embodiments, the initial donor substrate 300 may be reclaimable multiple times to enable the layer transfer and reclaim cycle to be repeated multiple times, producing multiple transferred device layers 108 on multiple SOI structures 100. For example, the donor substrate 300 may be reclaimed to produce transferred device layers 108 on at least (i.e., greater than or equal to) two SOI structures, at least three SOI structures, at least four SOI structures, or at least five SOI structures. In some embodiments, the donor substrate 300 may be reclaimed to produce transferred device layers 108 on ten SOI structures 100, or even more than ten SOI structures. Each SOI structure 100 prepared using the donor substrate 300, or a reclaimed donor substrate 500 derived from the donor substrate 300, may be prepared as described above with reference to FIGS. 2-7.

The number of times the donor substrate 300 can be reclaimed, and the number of transferred device layers 108 that may be produced using the donor substrate 300, is suitably only limited by the denuded zone depth D₂ of the denuded zone DZ and cumulative reductions/removals of the denuded zone DZ for each transferred device layer 108. Alternatively stated, the low COP level and low BMD density of the donor substrate 300 are maintained in the reclaimed donor substrates 500 derived therefrom throughout multiple SOI processes, and the depth D₅ of the denuded zone DZ₂ in each successive reclaimed donor substrate 500 is suitably only reduced by cumulative material losses attributed to layer transfer of the device layer(s) 108. During production of SOI structures 100, the donor substrate 300 and the reclaimed donor substrate 500 derived therefrom are subjected to oxidation and/or annealing operations that create the propensity for grown-in defects (e.g., oxygen precipitates and/or COPs) to generate in the donor substrate 500. In the embodiments described herein, the denuded zone DZ formed at the denuded zone depth D₂ in the donor substrate 300 by the UHT RTP is maintained throughout oxidation and anneal cycles performed during SOI production that may otherwise result in the generation of grown-in defects such as oxygen precipitates and/or COPs.

The ability of the donor substrate 300 to withstand SOI processing cycles without generating grown-in defects in the denuded zone DZ, and therefore able to be reclaimed for the production of multiple defect-free transferred device layers 108, may be confirmed by performing simulated SOI oxidation cycles and/or simulated SOI thermal cycles on a donor substrate previously subjected to the UHT RTP, and measuring the donor substrate for oxygen precipitates and COP defects after the simulated SOI cycles. In some example embodiments, the simulated SOI oxidation cycles are performed at conditions that simulate multiple oxidation cycles (e.g., at least three oxidation cycles) that would be performed across multiple reclaims of the donor substrate in producing the dielectric layer 310 on the front surface 302 thereof. For example, a simulated SOI oxidation cycle may include thermally oxidizing the donor substrate 300 in a furnace such as an ASM A400 or an ASM A412, at a temperature in a range of from 750° C. to 1200° C., such as about 950° C., in an oxidizing ambient for a duration of at least about five hours, for example, between about five hours to about ten hours, or about seven hours.

In some example embodiments, the simulated SOI thermal cycles are performed at conditions that simulate thermal anneals that would be performed during SOI production. Additionally and/or alternatively, the simulated SOI thermal cycles long thermal cycles performed at conditions that accelerate defect growth, such as oxygen precipitate growth. Simulated SOI thermal cycles may be performed at temperatures of between about 800° C., which is the temperature at which oxygen precipitate growth accelerates, to about 1150° C., which is preferably the maximum temperature as oxygen precipitates begin to dissolve in the silicon wafer material above this temperature. In various examples, the simulated SOI thermal cycle may be performed at a temperature between about 800° C. and about 1150° C., such as between about 900° C. and about 1050° C. The duration of the simulated SOI thermal cycle may vary depending on the temperature selected; lower temperature anneals sufficient to grow defects such as oxygen precipitates are generally at least about 2 hours, such as between about 2 hours and about 20 hours, while higher temperature anneals may be shorter, such as between about 30 minutes to about 16 hours. The simulated SOI thermal cycle may, in some examples, occur at multiple temperatures, which may be achieved via ramped or stepped profiles. For example, a simulated SOI thermal cycle may include a two-step thermal cycle that includes a first heat treatment step performed at a temperature of between about 700° C. to about 850° C. for a duration of between about two hours to about five hours, and a second heat treatment step performed at a temperature of between about 950° C. to about 1050° C. for a duration of between about 15 hours to about 20 hours. The SOI thermal cycles described above may be performed in the presence of oxidizing gas (e.g., O₂ gas).

Following the simulated SOI oxidation cycle and/or SOI thermal cycle, the donor substrate 300 may be measured for oxygen precipitates and PFZ depth, as well as other grown-in bulk and surface defects. Suitably, following the simulated SOI oxidation cycle and/or the SOI heat treatment cycle described above, the donor substrate 300 maintains the denuded zone DZ having the denuded zone depth D₂ described above and characterized by BMDs within a BMD density range of less than about 1×10⁹ cm⁻³, less than about 1×10⁸ cm⁻³, less than about 1×10⁷ cm⁻³, or less than about 5×10⁶ cm⁻³, measured by LST. The donor substrate 300, at least to the denuded zone depth D₂, may also be characterized by lack of additional grown-in bulk and surface defects, for example, non-detectable FPDs and DSODs, zero I-defects (A-defects), and less than 20 COPs at no more than 0.026 μm size. Defect characterization of the donor substrate 300 following the simulated SOI cycles may be confirmed by microscopes, such as SEMs, Atomic Force Microscopes, and Interference Differential Contrast Optical Microscopes.

In certain embodiments, a gas phase selective etching method may be performed on the donor substrate following the simulated SOI processing cycles described above. The gas phase selective etching method provides a process for evaluating the quality of the donor substrate 300 and, more particularly, delineating grown-in defects in the donor substrate 300, such as COPs, oxygen precipitates, A-defects and other dislocations, DSODs, and others. The gas phase selective etching method is described, for example, in U.S. Pat. No. 9,343,379, issued May 17, 2016, the disclosure of which is hereby incorporated herein by reference in its entirety.

The gas phase selective etching may be performed in a suitable reactor, e.g., an epsilon E3000 single-wafer epitaxial reaction manufactured by ASM International or reactors marketed under the trade name Centura by Applied Materials.

In general, the gas phase selective etching method includes exposing the surface of the donor substrate 300 to a reducing atmosphere comprising a gaseous etchant at a temperature and duration sufficient to etch the surface of the semiconductor silicon substrate and delineate grown-in-defects disposed in the semiconductor silicon substrate. The gaseous etchant selected may include any gaseous material capable of etching silicon and delineating crystallographic defects, such as hydrogen chloride (HCl), hydrogen bromide (HBr), hydrogen iodide (HI), or combinations thereof. The gas phase selective etching may be performed at elevated temperatures, such as up to about 1100° C. or between about 850° C. to about 1100° C. The reducing atmosphere includes, for example, H₂, and facilitates removing oxide from the surface of the donor substrate 300 so that the gaseous etchant may react with the surface. The donor substrate 300 may be heated at a temperature of, for example, between about 900° C. to about 1250° C. during exposure to the reducing atmosphere and prior to the gaseous etchant being introduced. The temperature is then reduced to, for example, between about 850° C. to about 1100° C., and the gaseous etchant is introduced into the reducing atmosphere. The donor substrate 300 is held within the reducing atmosphere that includes the gaseous etchant for a suitable duration, which may vary depending on the concentration of the gaseous etchant, until the etch is complete. After the etch, the temperature is reduced for post-process handling of the donor substrate.

After the gas phase selective etching, the surface of the donor substrate 300 may then be scanned with an optical detection device to determine whether any grown-in-defects have been delineated following the simulated SOI processing cycles and the gas phase selective etching. Any defects in the donor substrate 300 may become more easily detectable either by removal of silicon from around the defect thereby exposing it so it can scatter light directly or by creating a faceted pit around the defect, which can scatter light making it detectable and observable as levels of laser light scatterings (LLS). Current results to date have shown that faceted pit formation is the dominant mechanism by which the defects are made detectable. COPs (DSOD sized) and oxygen precipitates will etch differently creating faceted features observed as LLS. Suitable devices include the Surfscan SP1^{DLS}, SP2, and SP3, all manufactured by KLA-Tencor.

In example embodiments, the donor substrate 300, having been subjected to the UHT RTP and subsequent SOI processing cycles, shows lack of observable LLS at 0.12 μm particle size measured after the gas phase selective etching method. In some examples, multiple gas phase selective etching tests may be performed in conjunction with SOI processing cycles to ensure that the donor substrate 300 is reclaimable for producing multiple defect-free device layers 108. For example, a donor substrate 300 may be subjected to a gas phase selective etching method after the UHT RTP is performed and a selected amount of material is removed (e.g., by polishing and/or cleaning techniques described above) from the front surface 302 of the donor substrate 300. Suitably, after the UHT RTP and initial material removal step, performing the gas phase selective etching method and subsequently measuring LLS on the donor substrate 300 reveals a lack of observable LLS at 0.12 μm particle size. Subsequently, a simulated SOI oxidation cycle may be performed on the donor substrate 300, followed by one or more cycles of removing additional material from the front surface 302 of the donor substrate 300, performing gas phase selective etching, and measuring the surface of the donor substrate 300 for LLS. Suitably, even after greater than about 25 μm material removal from the donor substrate 300 following the simulated SOI oxidation cycle, the donor substrate has a lack of observable LLS at 0.12 μm particle size measured after gas phase selective etching. The amount of material that may be removed from the donor substrate 300 while still being characterized by a lack of observable LLS at 0.12 μm particle size measured after gas phase selective etching may translate to the depth of the denuded zone DZ. In various embodiments, the donor substrate 300 has a lack of observable LLS at 0.12 μm particle size measured after gas phase selective etching, and after greater than about 50 μm, greater than about 100 μm, greater than about 150 μm, greater than about 200 μm, greater than about 250 μm, or greater than about 300 μm of material is removed from the donor substrate.

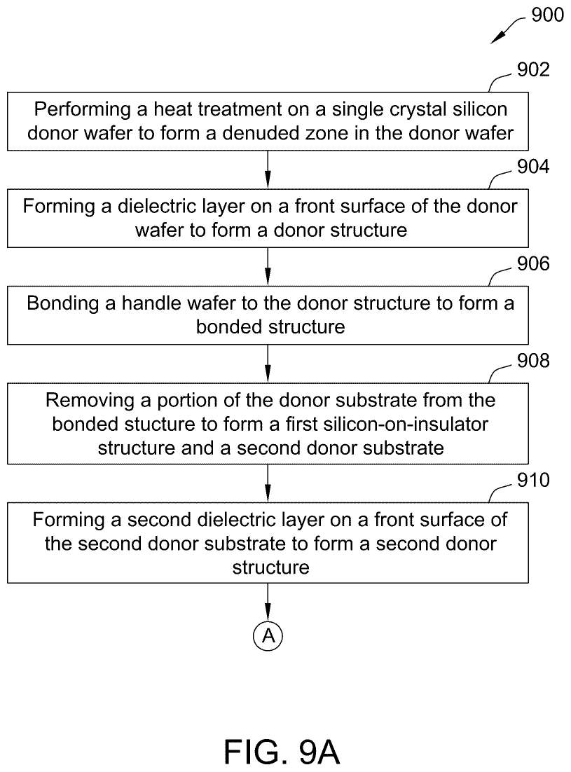

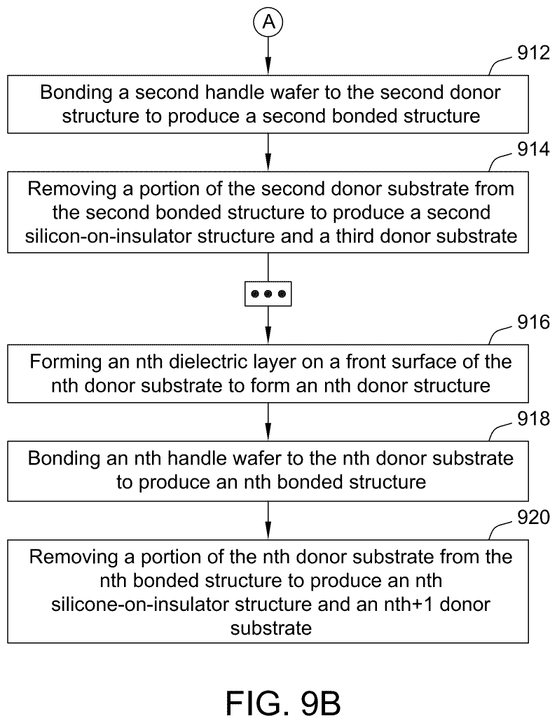

FIG. 9 depicts an example method 900 of preparing multiple silicon-on-insulator structures, such as multiple SOI structures 100 shown in FIG. 1, from a reclaimable single crystal silicon donor wafer, such as the donor substrate 300 shown in FIG. 4 and/or one or more of the reclaimed donor substrate 500 shown in FIG. 8 that is derived from the donor substrate 300. Each silicon-on-insulator structure prepared according to the method 900 may be prepared as described above with reference to FIGS. 1-8. The method 900 includes performing 902 a heat treatment on the single crystal silicon donor wafer, e.g., the donor substrate 300 shown in FIG. 4. The method 900 also includes forming 904 a dielectric layer, e.g., the dielectric layer 310, on a front surface 304 of the donor substrate 300 to thereby form a donor structure, e.g., the donor structure 350 shown in FIG. 5. The donor structure 350 includes the donor substrate 300 and the dielectric layer 310 in interfacial contact with the front surface 302 of the donor substrate. Forming 904 the dielectric layer 310 may be accomplished as described above, for example, by thermal oxidation, CVD oxide deposition, and/or atomic layer deposition.

The heat treatment is performed 902 in an oxidizing gas atmosphere at a temperature and for a duration sufficient such that the donor substrate 300 includes the denuded zone DZ. Moreover, the donor substrate 300 includes the denuded zone DZ after the donor structure 350 is formed, that is after the dielectric layer 310 is formed on the donor substrate 300. Alternatively stated, the heat treatment performed 902 on the donor substrate 300 is sufficient to facilitate forming the denuded zone DZ that withstands the conditions at which the dielectric layer 310 is formed on the donor substrate 300. In the example embodiment, the heat treatment performed on the donor substrate 300 to form the denuded zone DZ is the UHT RTP described above. The denuded zone DZ, as described above, extends from the front surface 302 of the donor substrate 300 the denuded zone depth D₂, and the denuded zone DZ is also characterized by non-detectable oxygen precipitates measured by LST. For example, the denuded zone DZ is characterized by BMDs within a BMD density range of less than about 1×10⁹ cm⁻³, less than about 1×10⁸ cm⁻³, less than about 1×10⁷ cm⁻³, or less than about 5×10⁶ cm⁻³, measured by LST. The denuded zone DZ may also be characterized by non-detectable FPDs and DSODs, zero I-defects (A-defects), and less than 20 COPs at no more than 0.026 μm size. When the donor structure 350 is formed, that is, after forming the dielectric layer 310 on the front surface 302 of the donor substrate 300, the donor substrate 300 is characterized by a lack of observable LLS at 0.12 μm particle size, measured after gas phase selective etching.

The donor substrate 300 has the interstitial oxygen concentration as described above. For example, the donor substrate 300 the interstitial oxygen concentration of the donor substrate 300 may be between about 1×10¹⁷ atoms/cm³ to about 1×10¹⁸ atoms/cm³. The donor substrate 300, as described above, may be also made of perfect silicon material that has vacancies as the dominant intrinsic point defects, interstitials as the dominant intrinsic point defects, or some combination thereof. Advantageously, the denuded zone DZ that is formed in the donor substrate 300 at the denuded zone depth D₂ enables the donor substrate 300 to have either vacancies or interstitials as the dominant-type of intrinsic point defect as well as a wider and/or higher range of interstitial oxygen than is typically accepted for donor substrates used to produce defect-free device layers in SOI structures. Moreover, the denuded zone enables multiple oxygen precipitate-free and COP-free device layers to be produced from the donor substrate 300, having relatively higher levels of interstitial oxygen and/or having vacancies as the dominant-type of intrinsic point defect.

The method 900 also includes bonding 906 a single crystal semiconductor handle wafer, e.g., the handle substrate 200, to the donor structure 350, to form a bonded structure, e.g., the bonded structure 400 shown in FIG. 7. The bonded structure 400 includes the handle substrate 200, the donor substrate 300, and the dielectric layer 310 disposed between the handle substrate 200 and the donor substrate 300. As described above, in some embodiments, a semiconductor layer 210 may be formed on the handle substrate 200 prior to bonding 906, and the bonded structure 400 may include the dielectric layer 310 and the semiconductor layer 210 in interfacial contact between the handle substrate 200 and the donor substrate 300.

After bonding 906, the method 900 includes removing 908 a portion of the donor substrate 300 from the bonded structure 400. The portion of the donor substrate 300 may be removed 908 by wafer thinning techniques described above, such as cleaving for example. The portion that is removed 908 from the donor substrate 300 includes a portion of the denuded zone DZ. Removing 908 the portion from the donor substrate 300 forms a first SOI structure, e.g., the SOI structure 100 shown in FIG. 1, that includes the handle substrate 102, optionally the semiconductor layer 104, the dielectric layer 106, and the device layer 108. The device layer 108 is derived from the denuded zone DZ of the donor substrate and is defect-free as described above.

After removing 908 the portion of the donor substrate 300 to achieve layer transfer of the device layer 108 and form the first SOI structure 100, a second donor substrate, e.g., the second or reclaimed donor substrate 500 shown in FIG. 8, remains and may be reclaimed to form a subsequent SOI structure. As described above, the reclaimed donor substrate 500 includes a second denuded zone DZ₂ that extends a second denuded depth D₅ from an exposed surface 502 of the reclaimed donor substrate 500. The second denuded zone depth D₅ is smaller than the denuded zone depth D₂ at least by a thickness of the device layer 108 transferred from the donor substrate 300 to form the first SOI structure 100. Like the denuded zone DZ of the donor substrate 300, the second denuded zone DZ₂ of the reclaimed donor substrate 500 is characterized by non-detectable oxygen precipitates measured by LST, and may also be characterized by non-detectable FPDs and DSODs, zero I-defects (A-defects), and less than 20 COPs at no more than 0.026 μm size, as well as a lack of observable LLS at 0.12 μm particle size, measured after gas phase selective etching.

Accordingly, the method 900 includes steps 910-914 for forming a second SOI structure 100 using the reclaimed donor substrate 500. The steps 910-914 are similar to steps 904-908 described above for forming the first SOI structure 100. In particular, the method 900 includes forming 910 a second dielectric layer 310 on the exposed surface 502 of the reclaimed donor substrate 500 to form a second donor structure, similar to the donor structure 350 described above. The method 900 also includes bonding 912 a second handle wafer, e.g., a second handle substrate 200, to the second donor structure 350 to form a second bonded structure. The second bonded structure may be similar to the bonded structure 400 described above, and includes the second handle substrate 200, the reclaimed donor substrate 500, and the second dielectric layer 310 disposed between the second handle substrate 200 and the reclaimed donor substrate 500, and may optionally include a second semiconductor layer 210 formed on the second handle substrate 200 and in interfacial contact with the second dielectric layer 310 between the second handle substrate 200 and the reclaimed donor substrate 500. The method also includes removing 914 a portion of the reclaimed donor substrate 500 from the second bonded structure 400 as described above, such as by cleaving for example. The portion that is removed 914 from the reclaimed donor substrate 500 includes a portion of the second denuded zone DZ₂, and removing 914 the portion from the donor substrate 500 forms a second SOI structure 100 that includes the handle substrate 102, optionally the semiconductor layer 104, the dielectric layer 106, and the device layer 108, where the device layer 108 is a second device layer derived from the second denuded zone DZ₂ of the reclaimed donor substrate 500 and is defect-free as described above.

After removing 914 the portion of the reclaimed donor substrate 500 to achieve layer transfer of the second device layer 108 and form the second SOI structure 100, a third donor substrate, e.g., another reclaimed donor substrate 500 shown in FIG. 8, remains and may be reclaimed to form a subsequent SOI structure. The subsequently reclaimed donor substrate includes a third denuded zone that extends a third denuded depth that is smaller than the second denuded zone depth D₅ at least by a thickness of the second device layer 108 transferred from the reclaimed donor substrate 500 to form the second SOI structure 100. Like the denuded zone DZ of the donor substrate 300 and the second denuded zone DZ₂ of the reclaimed donor substrate 500, the third denuded zone is characterized by non-detectable oxygen precipitates measured by LST, and may also be characterized by non-detectable FPDs and DSODs, zero I-defects (A-defects), and less than 20 COPs at no more than 0.026 μm size, as well as a lack of observable LLS at 0.12 μm particle size, measured after gas phase selective etching.

As depicted in FIG. 9, the sequence of steps 910-914 of the method 900 described above may repeat until a desired number of SOI structures 100 have been formed using the reclaimed donor substrate 500 and/or until the cumulative loss of material from the reclaimed donor substrate 500 for each transferred device layer 108 has exhausted the denuded zone from the reclaimed donor substrate. For example, the method 900 may repeat until three SOI structures 100, four SOI structures 100, five SOI structures 100, or more than five SOI structures 100, such as ten SOI structures 100, have been formed with device layers 108 transferred from successive reclaims of the donor substrate 300.

In a final sequence, the method 900 includes forming 916 an nth dielectric layer 310 on the exposed surface 502 of a donor substrate that has been reclaimed n−1 times from the donor substrate 300, where n is an integer greater than two, such as three, four, five, or more than five, such as ten, to form an nth donor structure 350. The final sequence of the method 900 also includes bonding 918 an nth handle substrate 200 to the nth donor structure 350 to form an nth bonded structure 400, and removing 920 a portion of the n^{th}−1 reclaimed donor substrate from the n^{th} bonded structure 400 to forms an n^{th} SOI structure 100. The n^{th} SOI structure 100 includes the handle substrate 102, optionally the semiconductor layer 104, the dielectric layer 106, and the device layer 108, where the device layer 108 is an n^{th} device layer derived from the denuded zone of the n^{th}−1 reclaimed donor substrate and is defect-free as described above. In the final sequence, after removing 920 the portion of the donor substrate that has been reclaimed n−1 times from the donor substrate 300 to form the n^{th} SOI structure 100, a final or sacrificial donor substrate remains. The final donor substrate remaining after the final removing 920 step may be devoid of any remaining denuded zone, or any remaining denuded zone may not be of sufficient depth for practical reclaim, and the final donor substrate may be scrapped accordingly.

The following non-limiting examples further illustrate the subject matter of the present disclosure.

As demonstrated, by applying a UHT RTP as described herein (e.g., at an RTP greater than 1275° C. or greater than 1300° C. in O₂ gas oxidizing atmosphere) to perfect silicon donor wafers with either Pi or Pv band structure and interstitial oxygen concentrations as high as 7.5×10¹⁷ atoms/cm³, the surface of the silicon donor wafer can be maintained COP-free with a PFZ (or denuded zone) of greater than 300 μm in depth. Selective gas phase etching results post SOI oxidation that simulate up to three oxidation reclaim cycles and after more than 25 μm polish removal reveal that the donor wafers remain free of harmful LLS counts, thereby enabling up to 5× and even 10× reclaims.

### Example 1

Comparison of results of LLS measured after gas phase selective etching results between perfect silicon wafers subjected to UHT RTP prior to SOI oxidation simulation vs. perfect silicon wafers that skipped UHT RTP prior to SOI oxidation simulation.

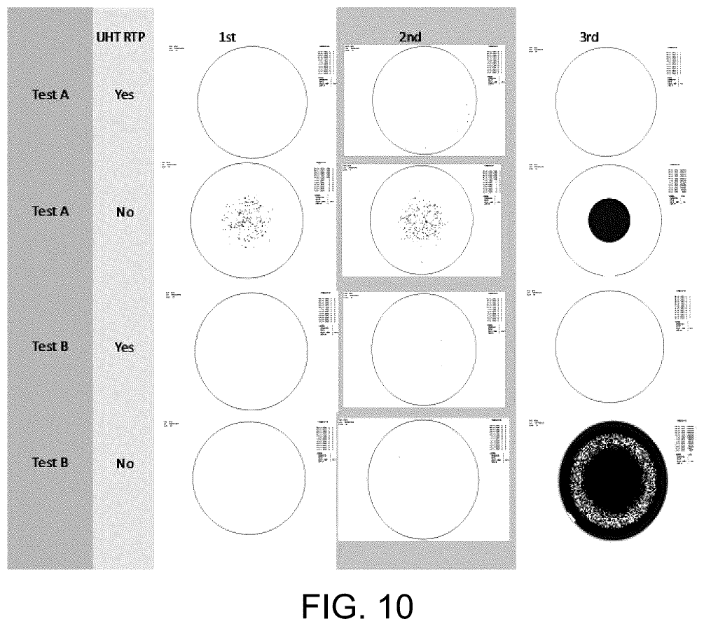

Two groups of perfect silicon (Pv-type) donor wafers were tested. The first group of wafers (“Test A”) had an interstitial oxygen concentration of 9.15 nppma (˜4.6×10¹⁷ atoms/cm³, ASTM F121-80). The second group of wafers (“Test B”) had an interstitial oxygen concentration of 9.7 nppma (˜4.6×10¹⁷ atoms/cm³, ASTM F121-80). One wafer from each group was pre-cleaned and subjected to UHT RTP, while the other wafer did not undergo UHT RTP. A first set included the wafer from each group that was pre-cleaned and then subjected to UHT RTP. A second set included the other wafer from each group that skipped the UHT RTP step. The UHT RTP condition for each wafer that underwent the heat treatment was 1300° C. for 30 sec. in 100% O₂ gas oxidizing atmosphere then cooled at 120° C./s. The UHT RTP wafers were then polished with 5 μm removal. Both sets of wafers were subjected to a first gas phase selective etching process as described above. All wafers were then processed through a simulated SOI oxidation cycle (about seven hours at 950° C.), followed by SiO₂ film removal. All wafers were then subjected to a second gas phase selective etching process. The wafers then had ˜20 μm removal on each side with polishing, and the wafers were recleaned and subjected to a third gas phase selective etching process and characterization. LLS measurements were taken after gas phase selective etching process and are shown in FIG. 10.

In particular, FIG. 10 depicts LLS maps at 0.12 μm particle size or greater that were generated after each gas phase selective etching process. The LLS maps in FIG. 10 are organized by the type of perfect silicon wafer (Test A or Test B). Whether UHT RTP was performed on the wafer prior to the simulated SOI oxidation cycle is also indicated in FIG. 10. The LLS maps, in left-to-right arrangement in FIG. 10, show the results taken after the first, second, and third gas phase selective etching process, respectively. As shown, the LLS results measured after gas phase selective etching clearly show that the UHT RTP process creates a very deep PFZ after the simulated SOI oxidation cycle such that no defects are observed even after more than 25 μm of removal, thus enabling multiple reclaims even if Pv type perfect silicon is used. This is in contrast to wafers that did not have the UHT RTP process. The Test A wafer that was not subjected to UHT RTP did not pass LLS measured after the first gas phase selective etching process and the Test A wafer and the Test B wafer that both were not subjected to UHT RTP did not pass LLS measured after the third gas phase selective etching process.

### Example 2

Oxygen precipitate measurements in perfect silicon wafers taken by light scattering tomography after simulated SOI oxidation cycle.

Light scattering tomography (LST) was used to evaluate the Test A and Test B wafers described in Example 1 above and compare BMD density and PFZ depth after the SOI oxidation cycle described in Example 1. As described above, prior to the SOI oxidation cycle, one Test A wafer and one Test B wafer was subjected to UHT RTP, while the other wafer from each group skipped UHT RTP.

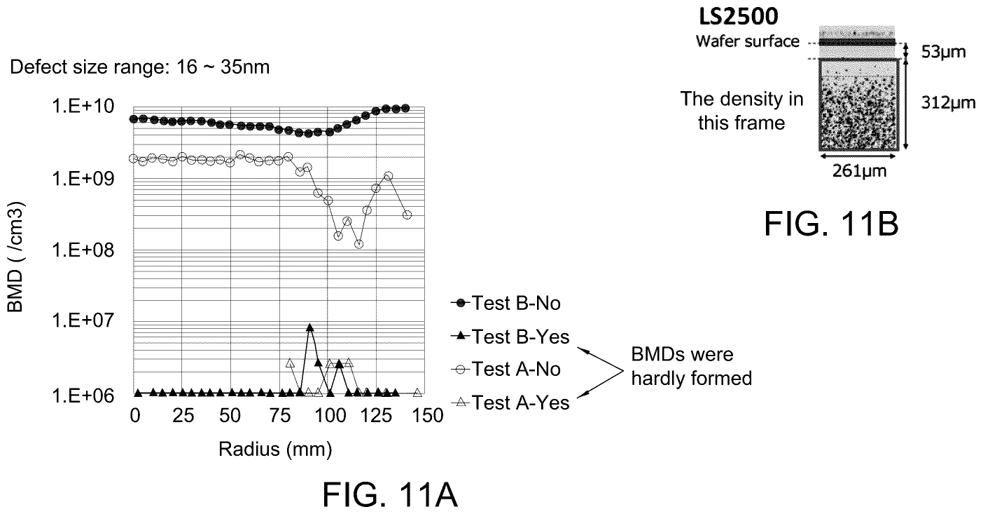

FIGS. 11A and 11B depict LST measurements of the Test A and Test B wafers taken using an LST2500 tool to evaluate the BMD density and PFZ depth post the SOI oxidation cycle on the Test A and Test B wafers with and without the UHT RTP process. The defect size range was 16-35 nm. As shown, the wafer from both Test A and Test B that was subjected to the UHT RTP process has negligible defect (BMD) density, that is, less than 1×10⁷ cm⁻³, which is the near detection limit of the LST2500 tool. The BMD profile for the wafers from Test A and Test B that skipped the UHT RTP process had defect density and radial profile consistent with Pv type perfect silicon having about 9.5 nppma interstitial oxygen concentration.

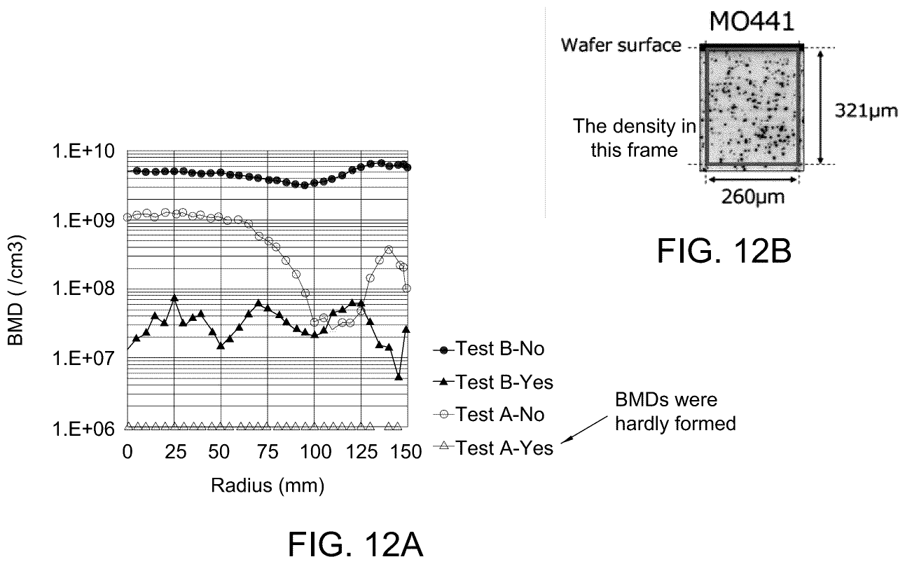

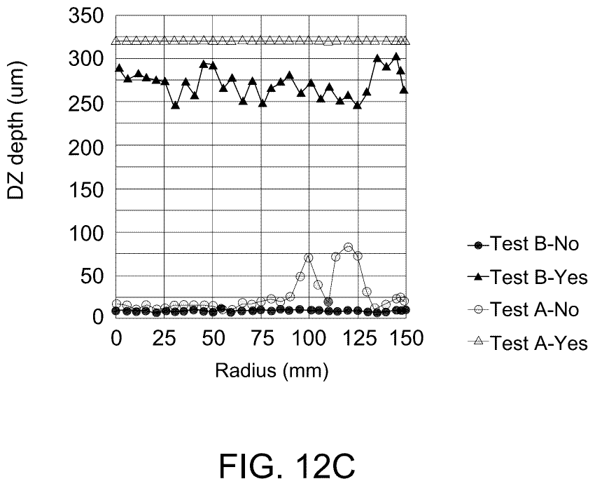

Referring to FIGS. 12A-12C, the BMD density and PFZ depth were also measured by a MO441 tool on the Test A and Test B wafers with and without UHT RTP. In this example, the LST measurements of Test A and Test B wafers were taken after a two-step oxygen precipitate growth thermal cycle. For the wafers that were subjected to UHT RTP, this was performed prior to the two-step thermal cycle. BMD density was measured as defect sizes between 39-95 nm as shown in FIG. 12a (BMD density) and FIG. 12c (PFZ depth in μm). The two-step oxygen precipitate growth thermal cycle included a first step performed at 780° C. for three hours and a second step performed at 1000° C. for 16 hours in O₂. As shown in FIG. 12a, Test A and B wafers that were subjected to UHT RTP prior to the two-step thermal cycle showed very low BMD density, less than 5×10⁷ cm⁻³ with corresponding very wide PFZ depths, greater than 200 μm. This deep PFZ depth agrees well with the lack of LLS in each wafer that was subjected to UHT RTP after the third gas phase selective etching results post more than 25 μm polish removal (shown in FIG. 10).

### Example 3

Comparison of the effect of different UHT RTP conditions on oxygen precipitate and COP dissolution.

A separate experiment with different UHT RTP conditions was conducted to confirm the minimum temperature for dissolution of as-grown precipitates in COP core-edge ring type material. Selected sample wafers used for the testing in this example have COPs detected at the wafer core and edge ring. LLS measurements taken by a MO441 tool after the two-step thermal cycle described above in Example 2 were used to confirm the LLS pattern from each UHT RTP condition. SEM inspection was used to confirm if COPs were dissolved by UHT RTP. The results from the various UHT RTP conditions are summarized in Table 1.

TABLE 1
Summary of Different UHT RTP Test Conditions and Results

| | | | Void | Precipitate |
|---|---|---|---|---|
| | | | dissolution? | dissolution? |
| Soak Temp | Soak Time | | (19 nm | (two-step thermal |
| (° C.) | (seconds) | Gas | LLS & SEM) | cycle, MO441) |
| 1230 | 30 | O₂ | Partial | Partial |
| 1250 | 30 | O₂ | Partial | Partial |
| 1275 | 15-30 | O₂ | Partial | Partial |
| 1275 | 30 | O₂ | Partial | Partial |
| 1300 | 15-30 | O₂ | OK | OK |
| 1300 | 30 | O₂ | OK | OK |

As shown in Table 1, COPs did not completely dissolve at an RTP temperature of 1275° C. for 30 seconds, but were completely dissolved by an RTP temperature of 1300° C. for 15 seconds.

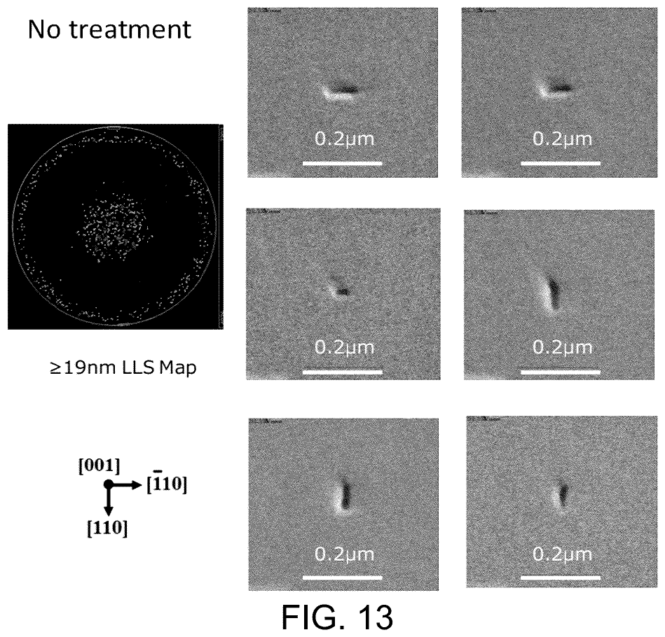

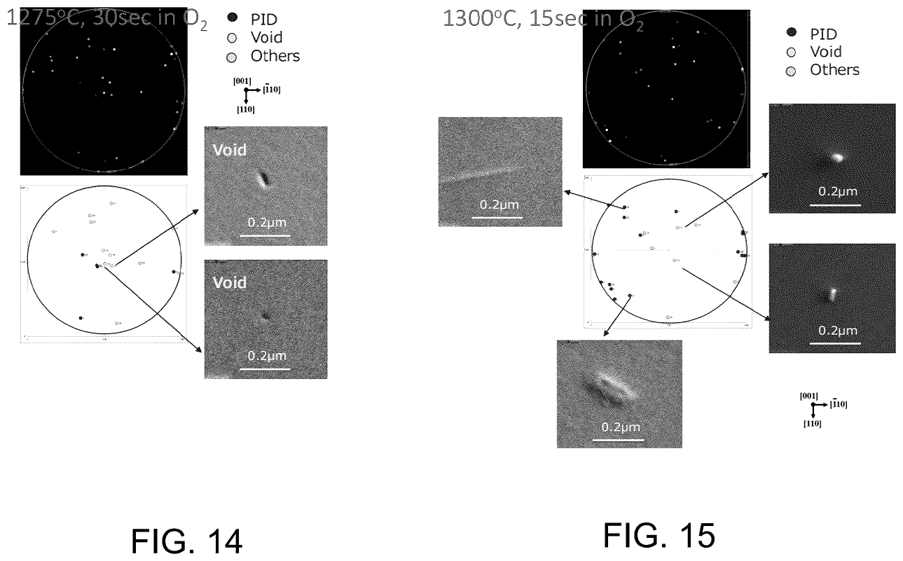

FIGS. 13-15 depict LLS pattern maps (taken after a two-step thermal cycle) and SEM defect images from different UHT RTP conditions. In particular, FIG. 13 depicts an LLS pattern map and SEM defect images following no UHT RTP treatment. FIG. 14 depicts an LLS pattern map and SEM defect images following UHT RTP performed at 1275° C. for 30 seconds. FIG. 15 depicts an LLS pattern map and SEM defect images following UHT RTP performed at 1300° C. for 15 seconds. A comparison between FIGS. 13-15 confirms the results of Table 1, where COPs did not completely dissolve at an RTP temperature of 1275° C. for 30 seconds, but were completely dissolved by an RTP temperature of 1300° C. for 15 seconds.

Perfect silicon wafers used as donor wafers in SOI application should not only be COP-free, but also be oxygen precipitate free. In particular, silicon donor wafers should lack any detectable oxygen precipitates after gas phase selective etching. Otherwise, the oxygen precipitates can act as a mask to an epi-smoothing etch performed on the transferred device layer in the SOI structure, creating defects that will affect device performance. Accordingly, the appropriate soak temperature and time for the UHT RTP should not only result in COP dissolution, but should also provide for dissolution of oxygen precipitates that are not detected by gas phase selective etching.

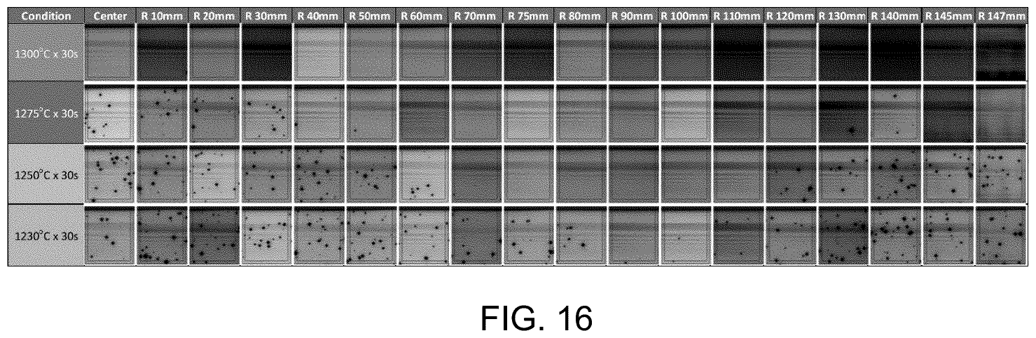

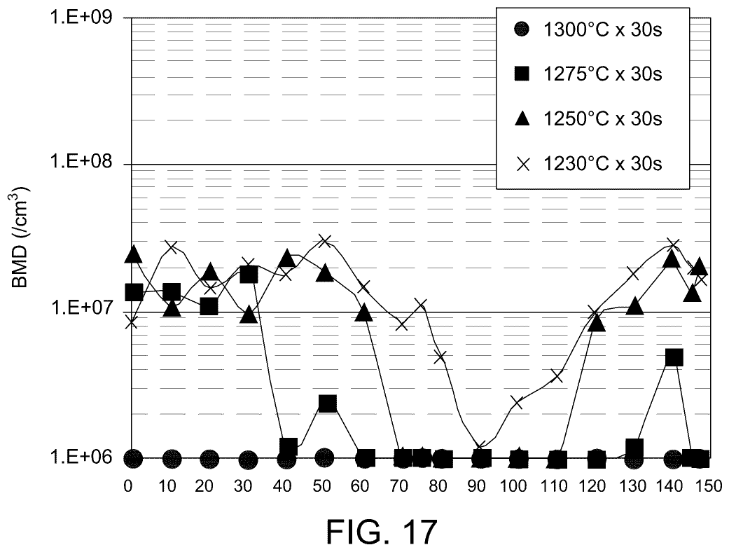

FIG. 16 depicts radial BMD distributions comparing the effect of oxygen precipitate dissolution from different UHT RTP conditions. FIG. 17 is a plot comparing the radial BMD distribution from the different UHT RTP conditions in FIG. 16. The BMD distributions in FIGS. 16 and 17 are from a MO441 tool after the two-step thermal cycle described above in Example 2 (780° C. for three hours and 1000° C. for 16 hours in O₂). As clearly indicated in FIGS. 16 and 17, the source of oxygen precipitate (as-grown oxygen precipitate) formed during crystal growth is completely dissolved by RTP at 1300° C. in O₂ condition.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” “front,” back,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

1. A donor structure for use in preparing silicon-on-insulator structures, the donor structure comprising:
a donor substrate made of single crystal silicon, the donor substrate comprising a front donor substrate surface, wherein the donor substrate has an interstitial oxygen concentration of less than 7.5×10¹⁷ atoms/cm³; and
a dielectric layer formed on the front donor substrate surface;
wherein the donor substrate comprises a denuded zone extending from the front donor substrate surface a denuded zone depth of at least 25 μm, wherein the denuded zone is characterized by non-detectable oxygen precipitates measured by light scattering tomography.

2. The donor structure of claim 1, wherein the donor substrate is characterized by a lack of observable levels of laser light scatterings (LLS) at 0.12 μm particle size, measured after gas phase selective etching.

3. The donor structure of claim 1, wherein the donor substrate is characterized by a bulk micro defect (BMD) density of less than 1×10⁹ cm⁻³, measured by light scattering tomography.

4.-6. (canceled)

7. The donor structure of claim 1, wherein the donor substrate is characterized by less than 20 crystal originated particle defects (COPs) at no more than 0.026 μm size.

8. The donor structure of claim 1, wherein the donor substrate has one of vacancies and interstitials as a dominant intrinsic point defect.

9.-11. (canceled)

12. The donor structure of claim 1, wherein the denuded zone depth is at least 100 μm.

13.-20. (canceled)

21. The donor structure of claim 1, wherein the donor substrate has the interstitial oxygen concentration of between 3×10¹⁷ atoms/cm³ to 7×10¹⁷ atoms/cm³.

22.-26. (canceled)

27. The donor structure of claim 1, wherein the dielectric layer comprises a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof.

28. A multilayer structure comprising:
a donor structure of comprising:
a donor substrate made of single crystal silicon, the donor substrate comprising a front donor substrate surface, wherein the donor substrate has an interstitial oxygen concentration of less than 7.5×10¹⁷ atoms/cm³; and
a dielectric layer formed on the front donor substrate surface;
wherein the donor substrate comprises a denuded zone extending from the front donor substrate surface a denuded zone depth of at least 25 μm, wherein the denuded zone is characterized by non-detectable oxygen precipitates measured by light scattering tomography; and
a handle substrate made of single crystal semiconductor material, the handle substrate comprising a front handle substrate surface bonded to the dielectric layer such that the dielectric layer is disposed between the handle substrate and the donor substrate.

29. The multilayer structure of claim 28, further comprising a semiconductor layer disposed between the front handle substrate surface and the dielectric layer.

30. (canceled)

31. The multilayer structure of claim 28, wherein the handle substrate is made of single crystal silicon.

32.-34. (canceled)

35. A method comprising:
performing a heat treatment on a donor substrate made of single crystal silicon, the donor substrate including a front donor substrate surface, the donor substrate having an interstitial oxygen concentration of less than 7.5×10¹⁷ atoms/cm³; and
forming a dielectric layer on the front donor substrate surface to thereby form the donor structure comprising the donor substrate and the dielectric layer in interfacial contact with the front donor substrate surface;
wherein the heat treatment is performed in an oxidizing gas atmosphere at a temperature and for a duration sufficient such that, when the donor structure is formed, the donor substrate comprises a denuded zone extending from the front donor substrate surface a denuded zone depth of at least 25 μm, wherein the denuded zone is characterized by non-detectable oxygen precipitates measured by light scattering tomography.

36. The method of claim 35, wherein the heat treatment is performed in the oxidizing gas atmosphere comprising 20% to 100% by volume oxygen (O₂) gas.

37.-39. (canceled)

40. The method of claim 35, wherein the heat treatment is performed at the temperature of at least 1275° C.

41.-45. (canceled)

46. The method of claim 35, wherein the heat treatment is performed for the duration of between 15 seconds to one minute.

47. (canceled)

48. (canceled)

49. The method of claim 35, wherein the heat treatment is performed for the duration of at least one minute.

50.-52. (canceled)

53. The method of claim 35, further comprising cooling the donor substrate after performing the heat treatment at a cooling rate of at least 10° C./sec.

54.-56. (canceled)

57. The method of claim 35, wherein, when the donor structure is formed, the donor substrate is characterized by a lack of observable levels of laser light scatterings (LLS) at 0.12 μm particle size, measured after gas phase selective etching.

58. The method of claim 35, wherein, when the donor structure is formed, the donor substrate is characterized by a bulk micro defect (BMD) density of less than 1×10⁹ cm⁻³, measured by light scattering tomography.

59.-61. (canceled)

62. The method of claim 35, wherein the donor substrate is characterized by less than 20 crystal originated particle defects (COPs) at no more than 0.026 μm size.

63. The method of claim 35, wherein the donor substrate has one of vacancies and interstitials as a dominant intrinsic point defect.

64.-66. (canceled)

67. The method of claim 35, wherein the denuded zone depth is at least 100 μm.

68.-75. (canceled)

76. The method of claim 35, wherein the donor substrate has the interstitial oxygen concentration of between 3×10¹⁷ atoms/cm³ to 7×10¹⁷ atoms/cm³.

77.-81. (canceled)

82. The method of claim 35, wherein the dielectric layer comprises a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof.

83. The method of claim 35, further comprising bonding a handle substrate made of single crystal semiconductor material to the donor structure to form a multilayer structure comprising the handle substrate, the donor substrate, and the dielectric layer disposed between the handle substrate and the donor substrate.

84. The method of claim 83, further comprising forming a semiconductor layer on a front handle substrate surface of the handle substrate prior to the bonding, wherein the semiconductor layer is bonded to the dielectric layer in the multilayer structure.

85. (canceled)

86. The method of claim 83, wherein the handle substrate is made of single crystal silicon.

87. The method of claim 83, further comprising:
removing a portion of the donor substrate from the multilayer structure to form a second donor substrate and a first silicon-on-insulator structure comprising the handle substrate, the dielectric layer, and a first device layer, wherein the second donor substrate comprises a second denuded zone extending from an exposed surface of the second donor substrate a second denuded zone depth that is smaller than the denuded zone depth at least by a thickness of the first device layer, wherein the second denuded zone is characterized by non-detectable oxygen precipitates measured by light scattering tomography;
forming a second dielectric layer on the exposed surface of the second donor substrate to form a second donor structure;
bonding a second handle substrate made of a single crystal semiconductor material to the second donor structure to form a second multilayer structure comprising the second handle substrate, the second donor substrate, and the second dielectric layer disposed between the second handle substrate and the second donor substrate; and
removing a portion of the second donor substrate from the second multilayer structure to form a third donor substrate and a second silicon-on-insulator structure comprising the second handle substrate, the second dielectric layer, and a second device layer.

88. (canceled)

89. (canceled)
